(19) United States
(12) Patent Application Publication
(10) Pub. No.: US 2015/0179494 A1
(43) Pub. Date: Jun. 25, 2015

(54) METHOD FOR PRODUCING SEMICONDUCTOR DEVICE

(71) Applicant: HITACHI CHEMICAL COMPANY, LTD., Chiyoda-ku, Tokyo (JP)

(72) Inventors: Takashi Kawamori, Tsukuba-shi (JP); Tatsuya Makino, Tsukuba-shi (JP); Shogo Young Sobue, Tsukuba-shi (JP); Keiichi Hatakeyama, Tsukuba-shi (JP); Takayuki Matsuzaki, Tsukuba-shi (JP)

(21) Appl. No.: 14/411,621

(22) PCT Filed: Jun. 26, 2013
(86) PCT No.: PCT/JP2013/067513

§ 371 Date: Dec. 29, 2014

(30) Foreign Application Priority Data
Jun. 29, 2012 (JP) 2012-147107

(51) Int. Cl. H01L 21/683; H01L 21/304; H01L 21/78

(52) U.S. Cl. CPC H01L 21/6836; H01L 21/78; H01L 21/304; H01L 2221/68327; H01L 2221/68386

(57) ABSTRACT

A method for producing a semiconductor device having a semiconductor element obtained by dividing a semiconductor wafer comprises a temporary securing step of arranging a temporary securing film between a support member and the semiconductor wafer so as to temporarily secure the support member and the semiconductor wafer to each other; a grinding step of grinding a surface on the side opposite from the temporary securing film of the semiconductor wafer temporarily secured to the support member, and a semiconductor wafer peeling step of peeling the temporary securing film from the ground semiconductor wafer, wherein a semiconductor wafer edge-trimmed on an outer peripheral part of a surface opposing the support member is used as the semiconductor wafer, and the temporary securing step arranges the temporary securing film on the inside of the edge-trimmed part.

### TECHNICAL FIELD

The present invention relates to a method for producing a semiconductor device.

### BACKGROUND ART

In the field of semiconductor devices, techniques concerning a package known as SIP (System in Package) in which a plurality of semiconductor elements are stacked have been growing remarkably. The SIP type package requires semiconductor elements to be as thin as possible, since a number of semiconductor elements are stacked therein. Such a semiconductor is made, for example, by incorporating an integrated circuit into a semiconductor wafer having a fixed thickness, grinding the rear face of the semiconductor wafer so as to make it thinner, and then dividing the thinned semiconductor wafer. The semiconductor wafer is processed while being temporarily secured to a support member with a temporary securing material (see Patent Literatures 1 and 2). As the temporary securing material, Patent Literatures 1 and 2 disclose a silicone adhesive and a composition mainly composed of rubber, respectively.

For connecting semiconductor elements, wire bonding has conventionally been the mainstream, but a connecting method known as TSV (through-silicon via) has recently been attracting attention and vigorously under study. When making a semiconductor element having a through-electrode, processing for forming the through-electrode is performed after thinning the semiconductor wafer. This involves a high-temperature process in which the semiconductor wafer is heated to about 300° C.

Therefore, the temporary securing material used in the manufacturing steps mentioned above is required to have adhesiveness for firmly securing the support member and the semiconductor wafer to each other at the time of grinding the semiconductor wafer and the like and heat resistance in the high-temperature process. On the other hand, it is necessary for the temporary securing material to have such releasability as to be able to separate the processed semiconductor wafer easily from the support member. In particular, the temporary securing material is required to be able to separate the semiconductor wafer and the support member from each other at a temperature as low as possible so as to prevent semiconductor chips from being damaged or warping.

### CITATION LIST

### Patent Literature

Patent Literature 1: Japanese Patent Application Laid-Open No. 2011-119427

Patent Literature 2: International Publication No. 2008/045669 pamphlet

### SUMMARY OF INVENTION

### Technical Problem

The temporary securing material disclosed in Patent Literature 1 mainly uses a silicone resin and thus tends to have poor compatibility with highly polar monomers such as acrylate resins and epoxy resins which become curable components, so that isolated monomers may form irregularities at the time of forming a film, thereby worsening film formability. The temporary securing material disclosed in Patent Literature 2 tends to fail to have sufficient heat resistance to high-temperature processes at the time of forming the through-electrode in the semiconductor wafer and at the time of connecting the semiconductor wafers, each formed with the through-electrode, to each other. When the heat resistance of the temporary securing member is insufficient, inconveniences are likely to occur; for example, the temporary securing material may thermally be decomposed during the high-temperature processes, so that the semiconductor wafer may peel off from the support member.

Typical resins excellent in heat resistance such as polyimides having a high glass transition temperature (Tg) may be used but, when in a film type, must be bonded at a high temperature, which may damage the semiconductor wafer, because of their high glass transition temperature in order to secure the semiconductor wafer and the support member sufficiently to each other. In the case of a varnish type different from the film type, on the other hand, the wafer is spin-coated with a varnish, which is then dried, so as to form a membrane, whereby fluctuations in thickness of the membrane, rises at wafer edges, difficulty in thickening the membrane, complication in the process, and the like may become problematic as the wafer is greater. When coating the support member therewith, fluctuations in thickness, difficulty in thickening the membrane, complication in the process, and the like may become problematic.

In view of the foregoing circumstances, it is an object of the present invention to provide a method for producing a semiconductor device having such low-temperature adhesiveness and sufficient heat resistance as to be able to fully secure a semiconductor wafer and a support member to each other even when bonding them at a low temperature, while making it possible to separate the processed semiconductor wafer easily from the support member.

When bonding the semiconductor wafer and the support member to each other with the temporary securing member interposed therebetween, the temporary securing member may protrude out of the outer periphery of the semiconductor wafer. When using the varnish type temporary securing material, the position at which the temporary securing member is arranged may be hard to control in particular. Hence, the temporary securing material having protruded out may also be ground when grinding the semiconductor wafer, thus leaving residues of the temporary securing material to the semiconductor wafer. It is therefore an object of the present invention to provide a method for producing a semiconductor device which can restrain the temporary securing member from leaving its residues to the semiconductor wafer.

### Solution to Problem

The method for producing a semiconductor device in accordance with the present invention is a method for producing a semiconductor device comprising a semiconductor element obtained by dividing a semiconductor wafer, the method comprising a temporary securing step of arranging a temporary securing film between a support member and the semiconductor wafer so as to temporarily secure the support member and the semiconductor wafer to each other, a grinding step of grinding a surface on the side opposite from the temporary securing film of the semiconductor wafer temporarily secured to the support member; and a semiconductor wafer peeling step of peeling the temporary securing film from the ground semiconductor wafer, wherein a semiconductor wafer edge-trimmed on an outer peripheral part of a surface opposing the support member is used as the semiconductor wafer, and the temporary securing step arranges the temporary securing film on the inside of the edge-trimmed part.

This semiconductor device producing method uses a semiconductor wafer edge-trimmed on an outer peripheral part of a surface opposing the support member as the semiconductor wafer. When arranging the temporary securing film between the support member and the semiconductor wafer, the temporary securing film is arranged on the inside of the edge-trimmed part of the semiconductor wafer. This makes it harder for the temporary securing film to protrude out of the edge-trimmed part of the semiconductor wafer when temporarily securing the support member and the semiconductor wafer to each other. Hence, the temporary securing film is less likely to be ground in the subsequent grinding step, which can restrain the temporary securing film from leaving its residues to the semiconductor wafer.

Preferably, the above-mentioned semiconductor device producing method further comprises a support member peeling step of peeling the temporary securing film from the support member, wherein a support member release-processed on a part or whole of a surface opposing the temporary securing film is used as the support member. This makes it easier to peel the temporary securing film from the support member and enables the support member to be reused.

Preferably, the release processing is conducted by at least one release agent selected from the group consisting of a surface modifier having a fluorine atom, a polyolefin-based wax, a silicone oil, a silicone oil a reactive group and a silicone-modified alkyd resin. This makes it easier to peel the temporary securing film from the support member.

Preferably, a temporary securing film comprising a (meth)acrylic copolymer having an epoxy group, obtained by polymerizing an acrylic monomer comprising an acrylate monomer having an epoxy group or a methacrylate monomer having an epoxy group, having a weight-average molecular weight of at least 100,000 and a Tg of −50° C. to 50° C. is used as the temporary securing film. This enables the temporary securing film to achieve low-temperature adhesiveness and heat resistance at the same time.

Preferably, a glycidyl acrylate monomer is used as the acrylate monomer having an epoxy group, and a glycidyl methacrylate monomer is used as the methacrylate monomer having an epoxy group. This also enables the temporary securing film to achieve low-temperature adhesiveness and heat resistance at the same time.

Preferably, as the temporary securing film, a temporary securing film containing a release agent made of a silicone-modified alkyd resin is used. This can secure heat resistance of the temporary securing film, while making it easy to peel the temporary securing film from the semiconductor wafer.

### Advantageous Effects of Invention

The present invention can provide a method for producing a semiconductor device having such low-temperature adhesiveness and sufficient heat resistance as to be able to fully secure a semiconductor wafer and a support member to each other even when bonding them at a low temperature, while making it possible to separate the processed semiconductor wafer easily from the support member. The present invention can also restrain the temporary securing member from leaving its residues to the semiconductor wafer.

### BRIEF DESCRIPTION OF DRAWINGS

(A) in FIG. 1 is a top plan view illustrating an embodiment of a temporary securing film sheet in accordance with the present invention, while (B) in FIG. 1 is a schematic sectional view taken along the line I-I of (A) in FIG. 1;

(A) in FIG. 2 is a top plan view illustrating another embodiment of the temporary securing film sheet in accordance with the present invention, while (B) in FIG. 2 is a schematic sectional view taken along the line II-II of (A) in FIG. 2;

(A) in FIG. 3 is a top plan view illustrating still another embodiment of the temporary securing film sheet in accordance with the present invention, while (B) in FIG. 3 is a schematic sectional view taken along the line III-III of (A) in FIG. 3;

FIG. 4 is a perspective view for explaining an embodiment of the method for producing a semiconductor device in accordance with the present invention;

(A), (B) and (C) in FIG. 5 are schematic sectional views for explaining the embodiment of the method for producing a semiconductor device in accordance with the present invention, while (D) in FIG. 5 is a top plan view illustrating a semiconductor wafer after processing;

FIG. 6 is a set of schematic sectional views for explaining the embodiment of the method for producing a semiconductor device in accordance with the present invention;

FIG. 7 is a schematic sectional view for explaining a modified example of the semiconductor device producing method of FIG. 6;

FIG. 8 is a set of schematic sectional views for explaining another embodiment of the method for producing a semiconductor device in accordance with the present invention;

FIG. 9 is a schematic sectional view for explaining a modified example of the semiconductor device producing method of FIG. 8; and

FIG. 10 is a schematic sectional view for explaining an embodiment of the method for producing a semiconductor device in accordance with the present invention.

### DESCRIPTION OF EMBODIMENTS

First, the temporary securing film and temporary securing film sheet in accordance with the present invention will be explained. (A) in FIG. 1 is a top plan view illustrating an embodiment of the temporary securing film sheet in accordance with the present invention, while (B) in FIG. 1 is a schematic sectional view taken along the line I-I of (A) in FIG. 1.

A film sheet 1 illustrated in FIG. 1 comprises a support base 10, a temporary securing film 20 disposed on the support base 10, and a protective film 30 disposed on the temporary securing film 20 on the side opposite from the support base 10.

Examples of the support base 10 include polyester films, polypropylene films, polyethylene terephthalate films, polyimide films, polyetherimide films, polyether naphthalate films, and methylpentene films. The support base 10 may be a multilayer film combining two or more kinds of films. The support base 10 may also have a surface treated with a release agent of a silicone type, a silica type, or the like, for example.

The temporary securing film 20 comprises a polyimide resin obtained by reaction of a diamine and an acid dianhydride comprising 20 mol % or more, the total amount of the acid dianhydride, of a tetracarboxylic acid dianhydride represented by the following formula (I-1).

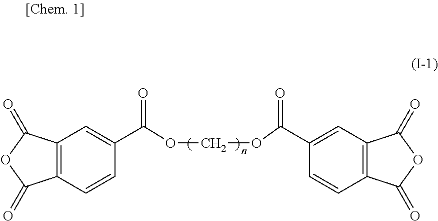

where n is an integer of 2 to 20.

By comprising the polyimide resin obtained by the above reaction as a thermoplastic resin having an imide skeleton, the temporary securing film 20 can fully secure a member to be processed and a member for supporting it under a low-temperature adhesion condition and can be dissolved with an organic solvent after the processing, so as to separate the processed member and the support member easily from each other.

Examples of the tetracarboxylic acid dianhydride having n of 2 to 5 in the formula (I-1) include 1,2-(ethylene)bis(trimellitate dianhydride), 1,3-(trimethylene)bis(trimellitate dianhydride), 1,4-(tetramethylene)bis(trimellitate dianhydride), and 1,5-(pentamethylene)bis(trimellitate dianhydride). Examples of the tetracarboxylic acid dianhydride having n of 6 to 20 in the formula (I-1) include 1,6-(hexamethylene)bis(trimellitate dianhydride), 1,7-(heptamethylene)bis(trimellitate dianhydride), 1,8-(octamethylene)bis(trimellitate dianhydride), 1,9-(nonamethylene)bis(trimellitate dianhydride), 1,10-(decamethylene)bis(trimellitate dianhydride), 1,12-(dodecamethylene)bis(trimellitate dianhydride), 1,16-(hexadecamethylene)bis(trimellitate dianhydride), and 1,18-(octadecamethylene)bis(trimellitate dianhydride). These may be used singly or in combinations of two or more.

The above tetracarboxylic acid dianhydride can be synthesized by reacting a trimellitic anhydride monochloride with its corresponding diol.

The amount of the tetracarboxylic acid dianhydride compounded in the acid dianhydride is preferably at least 30 mol %, more preferably at least 50 mol %, further preferably at least 70 mol %, based on the total amount of the acid dianhydride. If the compounded amount of tetracarboxylic acid dianhydride represented by the formula (I-1) falls within the above range, sufficient securing can be achieved even when the bonding temperature of the temporary securing film is set lower.

The polyimide resin in accordance with this embodiment may not only be one obtained by using the tetracarboxylic acid dianhydride represented by the formula (I-1) alone as the acid dianhydride to react with the diamine, but also one obtained by using the tetracarboxylic acid dianhydride together with other acid dianhydrides.

Examples of the other acid dianhydrides usable with the tetracarboxylic acid dianhydride of the formula (I-1) include pyromellitic acid dianhydride, 3,3′,4,4′-diphenyltetracarboxylic acid dianhydride, 2,2′,3,3′-diphenyltetracarboxylic acid dianhydride, 2,2-bis(3,4-dicarboxyphenyl)propane dianhydride, 2,2-bis(2,3-dicarboxyphenyl)propane dianhydride, 1,1-bis(2,3-dicarboxyphenyl)ethane dianhydride, 1,1-bis(3,4-dicarboxyphenyl)ethane dianhydride, bis(2,3-dicarboxyphenyl)methane dianhydride, bis(3,4-dicarboxyphenyl)methane dianhydride, bis(3,4-dicarboxyphenyl)sulfone dianhydride, 3,4,9,10-perylenetetracarboxylic acid dianhydride, bis(3,4-dicarboxyphenyl)ether dianhydride, benzene-1,2,3,4-tetracarboxylic acid dianhydride, 3,4,3′,4′-benzophenonetetracarboxylic acid dianhydride, 2,3,2′,3-benzophenonetetracarboxylic acid dianhydride, 2,3,3′,4′-benzophenonetetracarboxylic acid dianhydride, 1,2,5,6-naphthalenetetracarboxylic acid dianhydride, 2,3,6,7-naphthalenetetracarboxylic acid dianhydride, 1,2,4,5-naphthalenetetracarboxylic acid dianhydride, 1,4,5,8-naphthalenetetracarboxylic acid dianhydride, 2,6-dichloronaphthalene-1,4,5,8-tetracarboxylic acid dianhydride, 2,7-dichloronaphthalene-1,4,5,8-tetracarboxylic acid dianhydride, 2,3,6,7-tetrachloronaphthalene-1,4,5,8-tetracarboxylic acid dianhydride, phenanthrene-1,8,9,10-tetracarboxylic acid dianhydride, pyrazine-2,3,5,6-tetracarboxylic acid dianhydride, thiophene-2,3,4,5-tetracarboxylic acid dianhydride, 2,3,3′,4′-biphenyltetracarboxylic acid dianhydride, 3,4,3′,4′-biphenyltetracarboxylic acid dianhydride, 2,3,2′,3′-biphenyltetracarboxylic acid dianhydride, bis(3,4-dicarboxyphenyl)dimethylsilane dianhydride, bis(3,4-dicarboxyphenyl)methylphenylsilane dianhydride, bis(3,4-dicarboxyphenyl)diphenylsilane dianhydride, 1,4-bis(3,4-dicarboxyphenyldimethylsilyl)benzene dianhydride, 1,3-bis(3,4-dicarboxyphenyl)-1,1,3,3-tetramethyldicyclohexane dianhydride, p-phenylbis(trimellitic acid monoester acid anhydride), ethylenetetracarboxylic acid dianhydride, 1,2,3,4-butanetetracarboxylic acid dianhydride, decahydronaphthalene-1,4,5,8-tetracarboxylic acid dianhydride, 4,8-dimethyl-1,2,3,5,6,7-hexahydronaphthalene-1,2,5,6-tetracarboxylic acid dianhydride, cyclopentane-1,2,3,4-tetracarboxylic acid dianhydride, pyrrolidine-2,3,4,5-tetracarboxylic acid dianhydride, 1,2,3,4-cyclobutane tetracarboxylic acid dianhydride, bis(exo-bicyclo[2.2.1]heptane-2,3-dicarboxylic acid dianhydride) sulfone, bicyclo[2.2.2]oct(7)-ene-2,3,5,6-tetracarboxylic acid dianhydride, 2,2-bis(3,4-dicarboxyphenyl)hexafluoropropane dianhydride, 2,2-bis[4-(3,4-dicarboxyphenoxyl)phenyl]hexafluoropropane dianhydride, 4,4′-bis(3,4-dicarboxyphenoxy)diphenylsulfide dianhydride, 1,4-bis(2-hydroxyhexafluoroisopropyl)benzene bis(trimellitic anhydride), 1,3-bis(2-hydroxyhexafluoroisopropyl)benzene bis(trimellitic anhydride), 5-(2,5-dioxotetrahydrofuryl)-3-methyl-3-cyclohexene-1,2-dicarboxylic acid anhydride, and tetrahydrofuran-2,3,4,5-tetracarboxylic acid dianhydride. These may be used in combinations of two or more. Their compounding amount is preferably 90 mol % or less, more preferably 85 mol % or less, further preferably 80 mol % or less, with respect to the total amount of the acid dianhydride.

Examples of the diamine include o-phenylenediamine, m-phenylenediamine, p-phenylenediamine, 3,3′-diaminodiphenyl ether, 3,4′-diaminodiphenyl ether, 4,4′-diaminodiphenyl ether, 3,3′-diaminodiphenylmethane, 3,4′-diaminodiphenylmethane, 4,4′-diaminodiphenylmethane, bis(4-amino-3,5-dimethylphenyl)methane, bis(4-amino-3,5-diisopropylphenyl)methane, 3,3′-diaminodiphenyldifluoromethane, 3,4′-diaminodiphenyldifluoromethane, 4,4′-diaminodiphenyldifluoromethane, 3,3′-diaminodiphenylsulfone, 3,4′-diaminodiphenylsulfone, 4,4′-diaminodiphenylsulfone, 3,3′-diaminodiphenylsulfide, 3,4′-diaminodiphenylsulfide, 4,4′-diaminodiphenylsulfide, 3,3′-diaminodiphenyl ketone, 3,4′-diaminodiphenyl ketone, 4,4′-diaminodiphenyl ketone, 2,2-bis(3-aminophenyl)propane, 2,2′-(3,4′-diaminophenyl)propane, 2,2-bis(4-aminophenyl)propane, 2,2-bis(3-aminophenyl)hexafluoropropane, 2,2-(3,4′-diaminodiphenyl)hexafluoropropane, 2,2-bis(4-aminophenyl)hexafluoropropane, 1,3-bis(3-aminophenoxy)benzene, 1,4-bis(3-aminophenoxy)benzene, 1,4-bis(4-aminophenoxy)benzene, 3,3′-[1,4-phenylenebis(1-methylethylidene)]bisaniline, 3,4′-[1,4-phenylenebis(1-methylethylidene)]bisaniline, 4,4′-[1,4-phenylenebis(1-methylethylidene)]bisaniline, 2,2-bis[4-(3-aminophenoxyl)phenyl]propane, 2,2-bis[4-(3-aminophenoxyl)phenyl]hexafluoropropane, 2,2-bis[4-(4-aminophenoxyl)phenyl]hexafluoropropane, bis[4-(3-aminophenoxyl)phenyl]sulfide, bis[4-(4-aminophenoxyl)phenyl]sulfide, bis[4-(3-aminophenoxyl)phenyl]sulfone, bis[4-(4-aminophenoxyl)phenyl]sulfone, 1,3-bis(aminomethyl)cyclohexane, and 2,2-bis(4-aminophenoxyphenyl)propane.

The polyimide resin in accordance with this embodiment is obtained by reacting the acid dianhydride with a diamine comprising preferably at least 10 mol %, more preferably at least 20 mol %, further preferably at least 30 mol % of a diamine represented by the following formula (A-1), with respect to the total diamine amount.

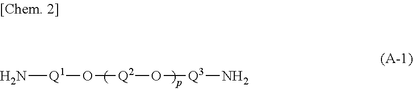

where Q¹, Q², and Q³ each independently represent an alkylene group having 1 to 10 carbon atoms, and p is an integer of 0 to 10.

By containing the polyimide resin in which the compounding amount of the diamine represented by the formula (A-1) falls within the above range, the temporary securing film can attain such a characteristic that it is excellent in low-temperature adhesiveness and low in stress. This can easily make it possible to suppress damages to the member to be temporarily secured and fully secure the member at the time of processing.

Examples of the alkylene group having 1 to 10 carbon atoms include groups such as methylene, ethylene, trimethylene, tetramethylene, pentamethylene, hexamethylene, heptamethylene, octamethylene, nonamethylene, decamethylene, propylene, butylene, amylene, and hexylene.

Examples of the diamine represented by the above formula (A-1) comprise H₂N—(CH₂)₃—O—(CH₂)₄—O—(CH₂)₃—NH₂, H₂N—(CH₂)₃—(CH₂)₅—O—(CH₂)₃—NH₂, H₂N—(CH₂)₃—O—(CH₂)—O—(CH₂)₂—O—(CH₂)₃—NH₂, and H₂N—(CH₂)₃—O—(CH₂)₂—O—(CH₂)—O—(CH₂)₂—O—(CH₂)₃—NH₂.

The diamines represented by the formula (A-1) may be used singly or in combinations of two or more.

Preferably, the polyimide resin in accordance with this embodiment is obtained by reacting the acid dianhydride with a diamine comprising at least 3 mol %, more preferably at least 5 mol %, further preferably at least 10 mol %, of a diamine represented by the following formula (A-2) with respect to the total diamine amount.

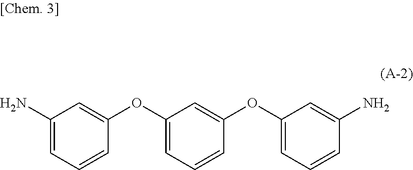 [SMILES: Nc1cccc(Oc2cccc(Oc3cccc(N)c3)c2)c1]

By containing the polyimide resin in which the compounding amount of the diamine represented by the formula (A-2) falls within the range mentioned above, the temporary securing film can attain such a characteristic that it is excellent in heat resistance and solubility in organic solvents. This can make it easier to process the temporarily secured member at a high temperature and separate the processed member and the support member from each other.

Preferably, the polyimide resin in accordance with this embodiment is obtained by reacting the acid dianhydride with a diamine comprising at least 3 mol %, more preferably at least 5 mol %, further preferably at least 10 mol %, of a diamine represented by the following formula (A-3) with respect to the total diamine amount. Preferably, the content of the diamine represented by the following formula (A-3) is 70 mol % or less of the total diamine amount.

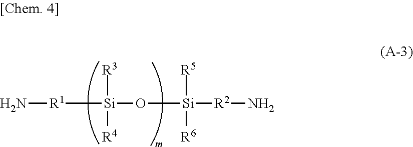

wherein R¹ and R² each independently represent an alkylene or phenylene group having 1 to 5 carbon atoms, R³, R⁴, R⁵, and R⁶ each independently represent an alkylene, phenylene, or phenoxy group having 1 to 5 carbon atoms, and m is an integer of 1 to 90.

By containing the polyimide resin in which the compounding amount of the diamine represented by the formula (A-3) falls within the range mentioned above, the temporary securing film can attain such a characteristic that it is excellent in low-temperature adhesiveness and low in stress. This can easily make it possible to suppress damages to the member to be temporarily secured and fully secure the member at the time of processing.

Examples of the diamine in which m is 1 in the formula (A-3) include 1,1,3,3-tetramethyl-1,3-bis(4-aminophenyl)disiloxane, 1,1,3,3-tetraphenoxy-1,3-bis(4-aminoethyl)disiloxane, 1,1,3,3-tetraphenyl-1,3-bis(2-aminoethyl)disiloxane, 1,1,3,3-tetraphenyl-1,3-bis(3-aminopropyl)disiloxane, 1,1,3,3-tetramethyl-1,3-bis(2-aminoethyl)disiloxane, 1,1,3,3-tetramethyl-1,3-bis(3-aminopropyl)disiloxane, 1,1,3,3-tetramethyl-1,3-bis(3-aminobutyl)disiloxane, and 1,3-dimethyl-1,3-dimethoxy-1,3-bis(4-aminobutyl)disiloxane.

Examples of the diamine in which m is 2 in the formula (A-3) include 1,1,3,3,5,5-hexamethyl-1,5-bis(4-aminophenyl)trisiloxane, 1,1,5,5-tetraphenyl-3,3-dimethyl-1,5-bis(3-aminopropyl)trisiloxane, 1,1,5,5-tetraphenyl-3,3-dimethoxy-1,5-bis(4-aminobutyl)trisiloxane, 1,1,5,5-tetraphenyl-3,3-dimethoxy-1,5-bis(5-aminopentyl)trisiloxane, 1,1,5,5-tetramethyl-3,3-dimethoxy-1,5-bis(2-aminoethyl)trisiloxane, 1,1,5,5-tetramethyl-3,3-dimethoxy-1,5-bis(4-aminobutyl)trisiloxane, 1,1,5,5-tetramethyl-3,3-dimethoxy-1,5-bis(5-aminopentyl)trisiloxane, 1,1,3,3,5,5-hexamethyl-1,5-bis(3-aminopropyl)trisiloxane, 1,1,3,3,5,5-hexaethyl-1,5-bis(3-aminopropyl)trisiloxane, and 1,1,3,3,5,5-hexapropyl-1,5-bis(3-aminopropyl)trisiloxane.

Examples of the diamine in which m is 3 to 70 in the formula (A-3) include a diamine represented by the following formula (A-4) and a diamine represented by the following formula (A-5).

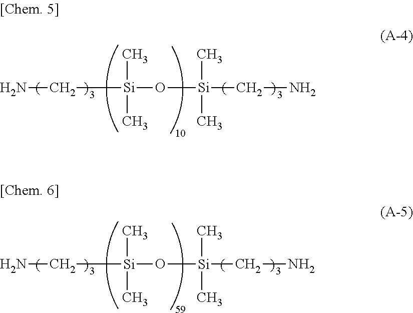

The diamines represented by the formula (A-3) may be used singly or in combinations of two or more.

In view of solubility in organic solvents and miscibility with other resins when forming the temporary securing film and solubility in organic solvents to come into contact therewith after the processing, it is preferred for this embodiment to use a siloxane diamine having a phenyl group in a part of a side chain of a silicone skeleton as the diamine represented by the formula (A-3).

The polyimide resin in accordance with this embodiment can be obtained by a condensation reaction between the acid dianhydride comprising the tetracarboxylic acid dianhydride in accordance with the present invention and a diamine in an organic solvent. In this case, it is preferred for the acid dianhydride and the diamine to be used at equimolar amounts or substantially equimolar amounts, and these ingredients can be added in any orders.

Examples of the organic solvent include dimethylacetamide, dimethylformamide, N-methyl-2-pyrrolidone, dimethylsulfoxide, hexamethylphosphoramide, m-cresol, and o-chlorophenol.

The reaction temperature is preferably 80° C. or lower, more preferably 0 to 50° C., further preferably 0 to 30° C., from the viewpoint of gelling prevention.

In the condensation reaction between the acid dianhydride and the diamine, polyamic acid which is a precursor of a polyimide is produced as the reaction proceeds, whereby the reaction liquid gradually raises its viscosity.

The polyimide resin in accordance with this embodiment can be obtained by cyclodehydrating the reaction product (polyamic acid) mentioned above. The cyclodehydration can be effected by a heat treatment method at 120° C. to 250° C. or a chemical method. The heat treatment method at 120° C. to 250° C. is preferably performed while removing water occurring in the dehydration reaction to the outside of the system. Here, benzene, toluene, xylene, or the like may be used for removing water azeotropically.

In this specification, polyimides and their precursors are collectively referred to as polyimide resin. The polyimide precursors comprise not only polyamic acid but also partially imidized polyamic acid.

In the cyclodehydration using the chemical method, acid anhydrides such as acetic anhydride, propionic anhydride, and benzoic anhydride and carbodiimide compounds such as dicyclohexylcarbodiimide can be used as cyclizing agents. Here, cyclizing catalysts such as pyridine, isoquinoline, trimethylamine, aminopyridine, and imidazole may also be used when necessary. The cyclizing agent or catalyst is used preferably within the range of 1 to 8 mol for 1 mol in total of the acid dianhydride.

The weight-average molecular weight of the polyimide resin is preferably 10,000 to 150,000, more preferably 30,000 to 120,000, further preferably 50,000 to 100,000, from the viewpoints of improving adhesive force and film formability. The above-mentioned weight-average molecular weight of the polyimide resin is one measured in terms of polystyrene by using high-performance liquid chromatography (e.g., HLC-8320GPC (product name) manufactured by Tosoh Corporation). It is preferred for this measurement to use an eluent in which lithium bromide and phosphoric acid are mixed and dissolved at concentrations of 3.2 g/L and 5.9 g/L, respectively, in a mixed solution in which tetrahydrofuran and dimethyl sulfoxide are mixed at a volume ratio of 1:1. As columns, TSKgel Pack AW2500, AW3000, and AW4000 manufactured by Tosoh Corporation can be used in combination.

The polyimide preferably has a glass transition temperature (Tg) of −20 to 180° C., more preferably 0 to 150° C., further preferably 25 to 150° C., from the viewpoints of thermal damage reduction at the time of attaching a wafer under pressure and film formability. The Tg of the polyimide resin is a peak temperature of tan δ when measuring a film by a viscoelastometer (manufactured by Rheometrics, Inc.). Specifically, a film having a thickness of 30 m is formed and cut into a size of 10 mm×25 mm, and its storage elastic modulus and temperature dependency of tan δ are measured under conditions with a temperature raising rate of 5° C./min, a frequency of 1 Hz, and a measurement temperature of −50 to 300° C., so as to calculate the Tg.

The temporary securing film 20 may further comprise an inorganic filler.

Examples of the inorganic filler include metal fillers such as powders of silver, gold, and copper and nonmetallic inorganic fillers such as silica, alumina, boron nitride, titania, glass, iron oxide, and ceramics.

The inorganic filler can be selected according to desired functions. For example, the metal fillers can be added in order to provide the temporary securing film with thixotropy, while the nonmetallic inorganic fillers can be added in order to provide the temporary securing film with low thermal expansibility and low hygroscopicity.

The inorganic fillers can be used singly or in combinations of two or more.

It is preferred for the inorganic filler to have an organic group on a surface. Modifying the surface of the inorganic filler with the organic group makes it easy to improve dispersibility into organic solvents at the time of forming the temporary securing film and the adhesion and heat resistance of the temporary securing film.

For example, the inorganic filler having an organic group on a surface can be obtained by mixing a silane coupling agent represented by the following formula (B-1) and an inorganic filler together and stirring them at a temperature of 30° C. or higher. The fact that the surface of the inorganic filler is modified with the organic group can be verified by UV measurement, IR measurement, XPS measurement, and the like.

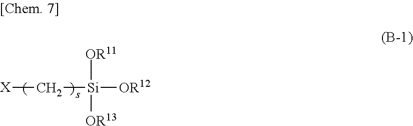

where X is an organic group selected from the group consisting of phenyl, glycidoxy, acryloyl, methacryloyl, mercapto, amino, vinyl, isocyanato, and methacryloxy groups, s is 0 or an integer of 1 to 10, and R¹¹, R¹², and R¹³ each independently represent an alkyl group having 1 to 10 carbon atoms.

Examples of the alkyl group having 1 to 10 carbon atoms include methyl, ethyl, propyl, butyl, pentyl, hexyl, heptyl, octyl, nonyl, decyl, isopropyl, and isobutyl groups. Methyl, ethyl, and pentyl groups are preferred from their easy availability.

Preferred as X from the viewpoint of heat resistance are amino, glycidoxy, mercapto, and isocyanato groups, among which glycidoxy and mercapto groups are more preferred.

In the formula (B-1), s is preferably 0 to 5, more preferably 0 to 4, from the viewpoints of suppressing the film fluidity at high temperatures and improving heat resistance.

Preferred examples of the silane coupling agent include trimethoxyphenylsilane, dimethyldimethoxyphenylsilane, triethoxyphenylsilane, dimethoxymethylphenylsilane, vinyltrimethoxysilane, vinyltriethoxysilane, vinyltris(2-methoxyethoxy)silane, N-(2-aminoethyl)-3-aminopropylmethyldimethoxysilane, N-(2-aminoethyl)-3-aminopropyltrimethoxysilane, 3-aminopropyltriethoxysilane, 3-aminopropyltrimethoxysilane, 3-glycidoxypropyltrimethoxysilane, 3-glycidoxypropylmethyldimethoxysilane, 2-(3,4-epoxycyclohexyl)ethyltrimethoxysilane, 3-isocyanatopropyltriethoxysilane, 3-methacryloxypropyltrimethoxysilane, 3-mercaptopropyltrimethoxysilane, 3-ureidopropyltriethoxysilane, N-(1,3-dimethylbutylidene)-3-(triethoxysilyl)-1-propanamine, N,N′-bis(3-(trimethoxysilyl)propyl)ethylenediamine, polyoxyethylenepropyltrialkoxysilane, and polyethoxydimethylsiloxane. Preferred among them are 3-aminopropyltriethoxysilane, 3-glycidoxypropyltrimethoxysilane, 3-isocyanatopropyltriethoxysilane, and 3-mercaptopropyltrimethoxysilane, while triethoxysilane, 3-glycidoxypropyltrimethoxysilane, and 3-mercaptopropyltrimethoxysilane are more preferred.

The silane coupling agents can be used singly or in combinations of two or more.

With respect to 100 parts by mass of the inorganic filler, the amount of use of the coupling agent is preferably 0.01 to 50 parts by mass, more preferably 0.05 to 20 parts by mass, from the viewpoint of attaining a balance between the heat resistance improving effect and storage stability, and further preferably 0.5 to 10 parts by mass from the viewpoint of improving the heat resistance.

When the temporary securing film in accordance with this embodiment contains the inorganic filler, its content is preferably 300 parts by mass or less, more preferably 200 parts by mass or less, further preferably 100 parts by mass or less, with respect to 100 parts by mass of the polyimide resin. The lower limit of the inorganic filler content is not restricted in particular, but is preferably at least 5 parts by mass with respect to 100 parts by mass of the polyimide resin.

The inorganic filler content falling within the range mentioned above can provide the temporary securing film with desirable functions while fully keeping its adhesiveness.

An organic filler can further be compounded in the temporary securing film in accordance with this embodiment. Examples of the organic filler include carbon, rubber-based fillers, silicone-based microparticles, polyamide microparticles, and polyimide microparticles.

The temporary securing film in accordance with this embodiment may further comprise a radically polymerizable compound having a carbon-carbon unsaturated bond and a radical generator.

An example of the radically polymerizable compound having a carbon-carbon unsaturated bond is a compound having an ethylenically unsaturated group.

Examples of the ethylenically unsaturated group include vinyl, allyl, propargyl, butenyl, ethynyl, phenylethynyl, maleimido, and (meth)acryloyl groups, among which (meth)acryloyl groups are preferred from the viewpoint of reactivity.

The radically polymerizable compound is preferably a bifunctional or higher functional (meth)acrylate. Examples of such an acrylate include diethyleneglycol diacrylate, triethyleneglycol diacrylate, tetraethyleneglycol diacrylate, diethyleneglycol dimethacrylate, triethyleneglycol dimethacrylate, tetraethyleneglycol dimethacrylate, trimethylolpropane diacrylate, trimethylolpropane triacrylate, trimethylolpropane dimethacrylate, trimethylolpropane trimethacrylate, 1,4-butanediol diacrylate, 1,6-hexanediol diacrylate, 1,4-butanediol dimethacrylate, 1,6-hexanediol dimethacrylate, pentaerythritol triacrylate, pentaerythritol tetraacrylate, pentaerythritol trimethacrylate, pentaerythritol tetramethacrylate, dipentaerythritol hexaacrylate, dipentaerythritol hexamethacrylate, styrene, divinylbenzene, 4-vinyltoluene, 4-vinylpyridine, N-vinylpyrrolidone, 2-hydroxyethyl acrylate, 2-hydroxyethyl methacrylate, 1,3-acryloyloxy-2-hydroxypropane, 1,2-methacryloyloxy-2-hydroxypropane, methylenebisacrylamide, N,N-dimethylacrylamide, N-methylolacrylamide, triacrylate of tris(3-hydroxyethyl)isocyanurate, compounds represented by the following formula (C-1), urethane acrylates, urethane methacrylates, urea acrylates, isocyanuric acid di/triacrylate, and isocyanuric acid di/trimethacrylate.

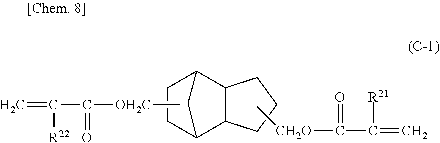

where R²¹ and R²² each independently represent a hydrogen or methyl group.

Among those mentioned above, compounds having the tricyclodecane skeleton as represented by the formula (C-1) are preferred in that they can improve the solubility and adhesiveness of the cured temporary securing film. Urethane acrylates, urethane methacrylates, isocyanuric acid di/triacrylate, and isocyanuric acid di/trimethacrylate are preferred in that they can improve the adhesiveness of the cured temporary securing film.

When the temporary securing film contains a trifunctional or higher functional acrylate compound as the radically polymerizable compound, the adhesiveness of the cured temporary securing film improves further, while outgassing is suppressed at the time of heating.

Preferably, the temporary securing film comprises isocyanuric acid di/triacrylate and/or isocyanuric acid di/trimethacrylate as the radically polymerizable compound from the viewpoint of further improving the heat resistance of the cured temporary securing film.

The radically polymerizable compounds may be used singly or in combinations of two or more.

Examples of the radical generator include thermal radical generators and photoradical generators. It is preferred for this embodiment to use a thermal radical generator such as an organic peroxide.

Examples of the organic peroxide include 2,5-dimethyl-2,5-di(t-butylperoxyhexane), dicumyl peroxide, t-butylperoxy-2-ethylhexanoate, t-hexylperoxy-2-ethylhexanoate, 1,1-bis(t-butylperoxy)-3,3,5-trimethylcyclohexane, 1,1-bis(t-hexylperoxy)-3,3,5-trimethylcyclohexane, and bis(4-t-butylcyclohexyl) peroxydicarbonate.

The organic peroxide is selected in view of conditions for forming the temporary securing film (e.g., film-making temperature), curing (bonding) conditions, other processing conditions, storage stability, and the like.

The organic peroxide used in this embodiment preferably has a one-minute half-life temperature of 120° C. or higher, more preferably 150° C. or higher. Examples of such an organic peroxide include PERHEXA 25B (manufactured by NOF Corporation), 2,5-dimethyl-2,5-di(t-butylperoxyhexane) (one-minute half-life temperature: 180° C.), PERCUMYL D (manufactured by NOF Corporation), and dicumyl peroxide (one-minute half-life temperature: 175° C.).

The radical generators may be used singly or in combinations of two or more.

From the viewpoint of improving the retention of a member (e.g., a semiconductor wafer) at the time of processing while fully securing the solubility of the cured temporary securing film, i.e., the releasability of the member, the radically polymerizable compound content in the temporary securing film is preferably 0 to 100 parts by mass, more preferably 3 to 50 parts by mass, further preferably 5 to 40 parts by mass, with respect to 100 parts by mass of the polyimide resin.

From the viewpoint of attaining not only curability but also outgassing suppression and storage stability, the radical generator content in the temporary securing film is preferably 0.01 to 20 parts by mass, more preferably 0.1 to 10 parts by mass, further preferably 0.5 to 5 parts by mass, with respect to 100 parts by mass of the total amount of the radically polymerizable compound.

The temporary securing film of this embodiment may further contain an epoxy resin as a thermosetting resin different from the above-mentioned radically polymerizable compound. In this case, an epoxy resin curing agent and a curing accelerator may further be compounded.

An example of the epoxy resin is a compound including at least two epoxy groups within a molecule thereof, and an epoxy resin of a phenol glycidyl ether type is preferably used from the viewpoints of curability and characteristics of the cured product. Examples of such a resin include condensation products of bisphenol A, bisphenol AD, bisphenol S, bisphenol F, or halogenated bisphenol A and epichlorohydrin; glycidyl ethers of phenol novolac resins; glycidyl ethers of cresol novolac resins; and glycidyl ethers of bisphenol-A novolac resins. These may be used in combinations of two or more.

The compounding amount of the epoxy resin is preferably 1 to 100 parts by mass, more preferably 5 to 60 parts by mass, with respect to 100 parts by mass of the polyimide resin. The epoxy resin compounding amount falling within the range mentioned above can sufficiently keep etching from taking time and lowering workability, while fully securing adhesiveness.

Examples of the epoxy resin curing agent include phenol resins and amine compounds. The phenol resins are used preferably because of their storage stability, inability to outgas at the time of curing, and compatibility with resins.

The compounding amount of the curing agent, which is preferably adjusted as appropriate in conjunction with the epoxy equivalent, is preferably 10 to 300 parts by mass, more preferably 50 to 150 parts by mass, with respect to 100 parts by mass of the epoxy resin. The compounding amount of the curing agent falling within the range mentioned above can make it easy to secure heat resistance.

Examples of the curing accelerator include imidazoles, dicyandiamide derivatives, dicarboxylic acid dihydrazides, triphenylphosphine, tetraphenylphosphonium tetraphenylborate, 2-ethyl-4-methylimidazole tetraphenylborate, and 1,8-diazabicyclo[5.4.0]undecene-7-tetraphenylborate. These may be used in combinations of two or more.

The compounding amount of the curing accelerator is preferably 0.01 to 50 parts by mass, more preferably 0.1 to 20 parts by mass, with respect to 100 parts by mass of the epoxy resin. The compounding amount of the curing accelerator falling within the range mentioned above can sufficiently keep storage stability from lowering, while attaining sufficient curability.

As the thermosetting compound in the temporary securing film in this embodiment, the epoxy resin may be compounded alone or together with the radically polymerizable compound. The content of the epoxy resin used together with the radically polymerizable compound is preferably 100 parts by mass or less, more preferably 50 parts by mass or less, further preferably 30 parts by mass or less, with respect to 100 parts by mass of the radically polymerizable compound from the viewpoints of achieving solubility and heat resistance at the same time.

From the viewpoint of improving solubility in organic solvents, it is preferred for the temporary securing film to contain at least one kind selected from the group consisting of surface modifiers having a fluorine atom, polyolefin waxes, and silicone oils.

Examples of the surface modifiers having a fluorine atom include commercially available products such as MEGAFACE (product name, manufactured by DIC Corporation), HYPERTECH (product name, manufactured by Nissan Chemical Industries, Ltd.), OPTOOL (product name, manufactured by Daikin Industries, Ltd.), and CHEMINOX (product name, manufactured by Unimatec Co., Ltd.).

Examples of the polyolefin waxes include waxes based on polyethylene, amides, and montanoic acid.

Examples of the silicone oils include a straight silicone oil (KF-96 (manufactured by Shin-Etsu Chemical Co., Ltd.)) and reactive silicone oils (X-22-176F, X-22-3710, X-22-173DX, and X-22-170BX (manufactured by Shin-Etsu Chemical Co., Ltd.)).

The fluorine-based surface modifiers, polyolefin waxes, and silicone oils may be used singly or in combinations of two or more.

The total content of the fluorine-based surface modifiers and polyolefin waxes in the temporary securing film is preferably 0.01 to 10 parts by mass, more preferably 0.1 to 5 parts by mass, further preferably 0.5 to 3 parts by mass, with respect to 100 parts by mass of the polyimide resin from the viewpoint of the balance between solubility and adhesiveness.

In an embodiment different from that mentioned above, the temporary securing film 20 comprises a (meth)acrylic copolymer having an epoxy group (hereinafter referred to as “acrylic copolymer”), obtained by polymerizing monomers containing a functional monomer such as an acrylate having an epoxy group and a methacrylate having an epoxy group, having a weight-average molecular weight of at least 100,000. Examples of the acrylic copolymer include (meth)acrylic acid ester copolymers and acrylic rubber, among which acrylic rubber is preferably used.

Examples of the acrylates having epoxy groups include glycidyl acrylate, 4-hydroxybutyl acrylate glycidyl ether, and 3,4-epoxycyclohexylmethyl acrylate. Examples of the methacrylates having epoxy groups include glycidyl methacrylate, 4-hydroxybutyl methacrylate glycidyl ether, and 3,4-epoxycyclohexylmethyl methacrylate. Among them, glycidyl acrylate and glycidyl methacrylate are preferred from the viewpoint of heat resistance.

Acrylic rubber, which is mainly composed of an acrylic acid ester, is rubber constituted by a copolymer of butyl acrylate and acrylonitrile or the like or a copolymer of ethyl acrylate and acrylonitrile or the like, for example.

The Tg of the acrylic copolymer is preferably −50° C. to 50° C. The acrylic copolymer having a Tg of 50° C. or lower can secure flexibility of the temporary securing film 20 and restrain low-temperature adhesiveness under pressure from lowering. When a bump or the like exists in the semiconductor wafer, embedding in the bump at 150° C. or lower becomes easier. On the other hand, the acrylic copolymer having a Tg of −50° C. or higher can restrain the temporary securing film 20 from having such high flexibility as to lower operability and releasability.

The Tg of the acrylic copolymer is a peak temperature of tan δ when measuring a film by a viscoelastometer (manufactured by Rheometrics, Inc.). Specifically, a film having a thickness of 30 μm is formed and cut into a size of 10 mm×25 mm, and its storage elastic modulus and temperature dependency of tan δ are measured under conditions with a temperature raising rate of 5° C./min, a frequency of 1 Hz, and a measurement temperature of −50 to 300° C., so as to calculate the Tg.

The weight-average molecular weight of the acrylic copolymer is preferably at least 100,000 but not more than 1,000,000. When the weight-average molecular weight is 100,000 or more, the heat resistance of the temporary securing film 20 can be secured. When the weight-average molecular weight is 1,000,000 or less, the temporary securing film 20 can be restrained from lowering its flow and adhesiveness. The weight-average molecular weight is expressed in terms of polystyrene using a calibration curve based on standard polystyrene in gel permeation chromatography (GPC).

The amount of the acrylate or methacrylate having an epoxy group contained in the acrylic copolymer is preferably 0.1 to 20% by mass, more preferably 0.3 to 15% by mass, further preferably 0.5 to 10% by mass, in terms of the compounding mass ratio at the time of synthesizing the copolymer. The compounding mass ratio falling within the range mentioned above can restrain flexibility from lowering, while achieving sufficient heat resistance.

Usable as the above-mentioned acrylic copolymer are those obtained by polymerizing methods such as pearl polymerization and solution polymerization as well as readily available ones such as HTR-860P (product name, manufactured by Nagase ChemteX Corporation).

The temporary securing film 20 may contain a curing accelerator for accelerating the curing of epoxy groups contained in the acrylic copolymer.

Examples of the curing accelerator include imidazoles, dicyandiamide derivatives, dicarboxylic acid dihydrazides, triphenylphosphine, tetraphenylphosphonium tetraphenylborate, 2-ethyl-4-methylimidazole tetraphenylborate, and 1,8-diazabicyclo[5.4.0]undecene-7-tetraphenylborate. These may be used in combinations of two or more.

The compounding amount of the curing accelerator is preferably 0.01 to 50 parts by mass, more preferably 0.1 to 20 parts by mass, with respect to 100 parts by mass of the acrylic copolymer. The compounding amount of the curing accelerator falling within the range mentioned above can sufficiently keep storage stability from lowering, while attaining sufficient curability.

Preferably, the temporary securing film 20 contains a silicone-modified alkyd resin. Examples of methods for yielding the silicone-modified alkyd resin include (i) a typical synthesis reaction for yielding an alkyd resin, i.e., reacting an organopolysiloxane as an alcohol component at the same time when reacting a polyhydric alcohol and a fatty acid, a polybasic acid, or the like with each other, and (ii) reacting an organopolysiloxane with a typical alkyd resin synthesized beforehand, and either the method (i) or (ii) may be used.

Examples of the polyhydric alcohol used as a material for the alkyd resin include dihydric alcohols such as ethylene glycol, diethylene glycol, triethylene glycol, propylene glycol, trimethylene glycol, tetramethylene glycol, and neopentyl glycol; trihydric alcohols such as glycerin, trimethylolethane, and trimethylolpropane; and tetrahydric or higher hydric alcohols such as diglycerin, triglycerin, pentaerythritol, mannitol, and sorbitol. These may be used singly or in combinations of two or more.

Examples of the polybasic acids used as a material for the alkyd resin include aromatic polybasic acids such as phthalic anhydride, isophthalic anhydride, and trimellitic anhydride; aliphatic saturated polybasic acids such as succinic acid, adipic acid, and sebacic acid; aliphatic unsaturated polybasic acids such as maleic acid, maleic anhydride, fumaric acid, itaconic acid, and citraconic anhydride; and polybasic acids formed by the Diels-Alder reaction such as cyclopentadiene-maleic anhydride adduct, terpene-maleic anhydride adduct, and rosin-maleic anhydride adduct. These may be used singly or in combinations of two or more.

The alkyd resin may further comprise a modifier or a crosslinking agent.

Examples of the modifier include octylic acid, lauric acid, palmitic acid, stearic acid, oleic acid, linoleic acid, linolenic acid, eleostearic acid, ricinoleic acid, and dehydrated ricinoleic acid; and coconut oil, linseed oil, tung oil, castor oil, dehydrated castor oil, soybean oil, safflower oil, and their fatty acids. These may be used singly or in combinations of two or more.

Examples of crosslinking agents include amino resins such as melamine resins and urea resins, urethane resins, epoxy resins, and phenol resins. Among them, amino resins are used preferably in particular. These are favorable in that aminoalkyd resins crosslinked by the amino resins are obtained. The crosslinking agents may be used singly or in combinations of two or more.

In the silicone-modified alkyd resin, an acid catalyst can be used as a curing catalyst. The acid catalyst is not limited in particular and can be selected as appropriate from acid catalysts known as crosslinking reaction catalysts for alkyd resins. Preferred examples of such an acid catalyst include organic acid catalysts such as p-toluenesulfonic acid and methanesulfonic acid. The acid catalysts may be used singly or in combinations of two or more. The compounding amount of the acid catalyst is typically selected within the range of 0.1 to 40 parts by mass, preferably 0.5 to 30 parts by mass, more preferably 1 to 20 parts by mass, with respect to 100 parts by mass of the total of the alkyd resin and crosslinking agent.

An example of the above-mentioned silicone-modified alkyd resin is TESFINE TA31-209E (product name, manufactured by Hitachi Kasei Polymer Co., Ltd.).

By containing the silicone-modified alkyd resin, the temporary secured film 20 can easily be released from a semiconductor wafer at a low temperature of 100° C. or thereunder without using any solvent.

The compounding amount of the silicone-modified alkyd resin is preferably 5 to 50 parts by mass, more preferably 10 to 20 parts by mass, with respect to 100 parts by mass of the acrylic copolymer. The compounding amount of the silicone-modified alkyd resin falling within the range mentioned above can achieve both of the adhesiveness at the time of processing the semiconductor wafer and releasability after the processing.

The temporary securing film 20 can be formed by the following procedure.

First, the above-mentioned polyimide resin and, if necessary, other ingredients such as inorganic fillers, radically polymerizable compounds, and radical generators are mixed and kneaded in an organic solvent, so as to prepare a varnish. The mixing and kneading can be performed by appropriately combining dispersers such as typical stirrers, kneaders, three-roll mills, and ball mills. The mixing and kneading in the case of compounding the inorganic fillers can also be performed by appropriately combining dispersers such as typical stirrers, kneaders, three-roll mills, and ball mills.

When the temporary securing film 20 comprises an acrylic copolymer, the acrylic copolymer, silicone-modified alkyd resin, and curing accelerator are mixed and kneaded as mentioned above, so as to prepare a varnish.

Examples of the organic solvent used for preparing the varnish include dimethylformamide, toluene, benzene, xylene, methylethyl ketone, tetrahydrofuran, ethylcellosolve, ethylcellosolve acetate, dioxane, cyclohexanone, ethyl acetate, butyl acetate, propyleneglycol monomethyl ether, and N-methylpyrrolidinone.

Subsequently, the varnish obtained above is applied onto the support base 10, so as to form a varnish layer, which is then dried by heating, whereby the temporary securing film 20 can be formed.

When compounding the radically polymerizable compound and radical generator, it is preferred for the varnish layer to be dried at such a temperature that the radically polymerizable compound fails to react enough during drying, while selecting such a condition that the solvent vaporizes sufficiently.

When compounding the curing accelerator in the acrylic copolymer, it is preferred for the varnish layer to be dried at such a temperature that the epoxy group fails to react enough during drying, while selecting such a condition that the solvent vaporizes sufficiently.

The temperature at which the radically polymerizable compound fails to react enough can specifically be set not higher than a peak temperature of the reaction heat obtained by DSC measurement using DSC (e.g., DSC-7 (product name) manufactured by PerkinElmer, Inc.) under conditions with a sample amount of 10 mg, a temperature raising rate of 5° C./min, and a measurement atmosphere of air.

Specifically, the varnish layer is dried by being heated for 0.1 to 90 min at 60 to 180° C., for example.

The thickness of the temporary securing film 20 is preferably 1 to 300 μm from the viewpoint of ensuring the function of temporary securing and suppressing the residual volatile content, which will be explained later, at the same time.

For obtaining a thicker film, preformed films each having a thickness of 100 μm may be bonded together. Using thus bonded films can reduce the residual solvent when making the thicker film, thereby sufficiently lowering the possibility of volatile components causing contamination.

Preferably, the residual volatile content in the temporary securing film is 10% or less in this embodiment. This can prevent voids from occurring within the film and losing reliability in processing and sufficiently reduce the possibility of volatile components contaminating surrounding materials and the member to be processed during processing including heating.

The residual volatile components in the temporary securing film are measured by the following procedure. For the temporary securing film cut into a size of 50 mm×50 mm, assuming M1 to be the initial weight, and M2 the weight after being heated for 3 hr in an oven at 160° C., the residual volatile content (%) is calculated from the expression of [(M2−M1)/M1]×100=residual volatile content (%).

While this embodiment forms the temporary securing film 20 and then mounts the protective film 30 thereon, so as to yield the temporary securing film sheet 1, the support base 10 may be removed from the formed temporary securing film 20, so as to produce the temporary securing film alone. From the viewpoint of storability, it is preferred to form a sheet without removing the support base 10.

Examples of the protective film 30 include polyethylene, polypropylene, and polyethylene terephthalate.

The temporary securing film in accordance with the present invention can be changed as appropriate according to its use.

(A) in FIG. 2 is a top plan view illustrating another embodiment of the temporary securing film sheet in accordance with the present invention, while (B) in FIG. 2 is a schematic sectional view taken along the line II-II of (A) in FIG. 2.

The temporary securing film sheet 2 illustrated in FIG. 2 has the same structure as with the temporary securing film sheet 1 except that the securing film 20 and protective film 30 have been cut beforehand according to the form of the member to be temporarily secured.

The temporary securing film sheet 2 is advantageous in that it is not necessary for the film to be cut into a wafer form after lamination.

(A) in FIG. 3 is a top plan view illustrating still another embodiment of the temporary securing film sheet in accordance with the present invention, while (B) in FIG. 3 is a schematic sectional view taken along the line III-III of (A) in FIG. 3.

The temporary securing film sheet 3 illustrated in FIG. 3 has the same structure as with the temporary securing film sheet 1 except that low-adhesive-force layers 40 having low-adhesive-force surfaces with an adhesive force smaller than that of their surrounding surfaces are formed on both sides of the temporary securing film 20. The low-adhesive-force layer 40 may be formed on one side of the temporary securing film 20 alone. The temporary securing film sheet 3 may be processed as illustrated in FIG. 2. In this case, the form of the low-adhesive-force layers 40 may be equivalent to or smaller than the cut temporary securing film 20.

The low-adhesive-force layers 40 can be formed, for example, by applying a varnish containing at least one kind of the above-mentioned surface modifiers having a fluorine atom, polyolefin-based waxes, and silicone oils to a predetermined part of the support base 10 and drying it, subsequently forming the temporary securing film 20, and then applying the varnish again to a predetermined part of the temporary securing film 20 and drying it. The low-adhesive-force layers 40 can also be provided by forming a low-adhesive-force film on a base beforehand from a varnish containing at least one kind of the above-mentioned surface modifiers having a fluorine atom, polyolefin-based waxes, and silicone oils and then mounting it on each side of the temporary securing film 20.

A method for producing a semiconductor device by using the above-mentioned temporary securing film 20 will now be explained.

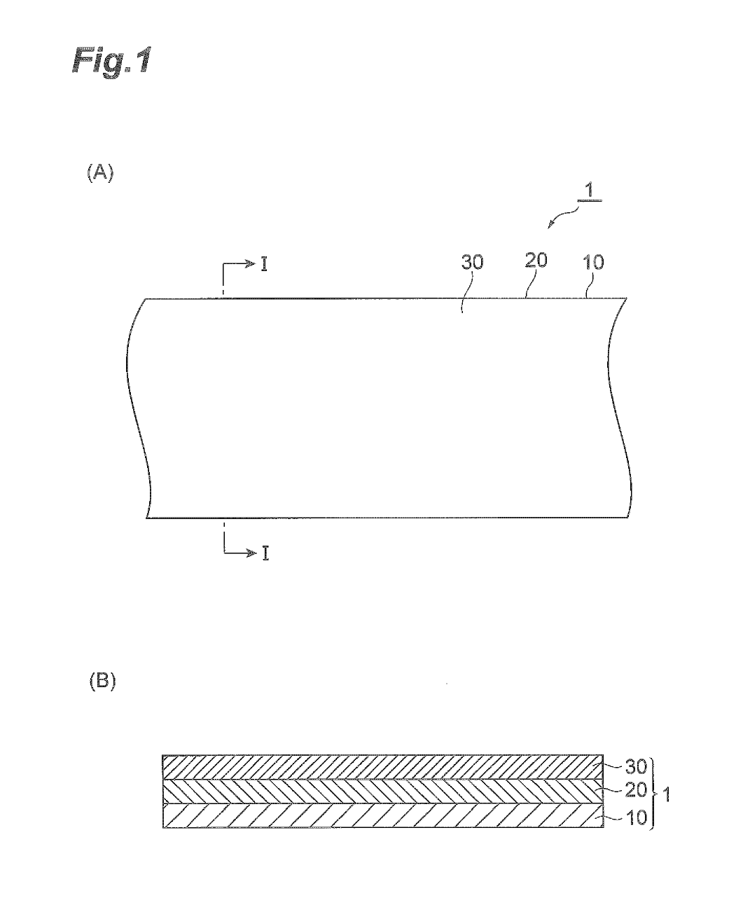

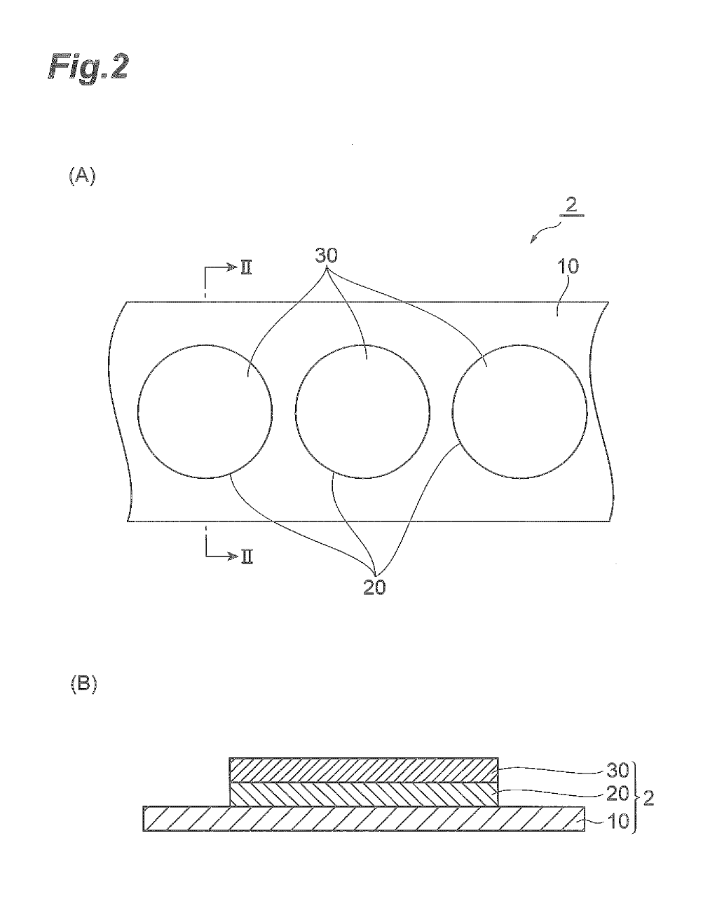

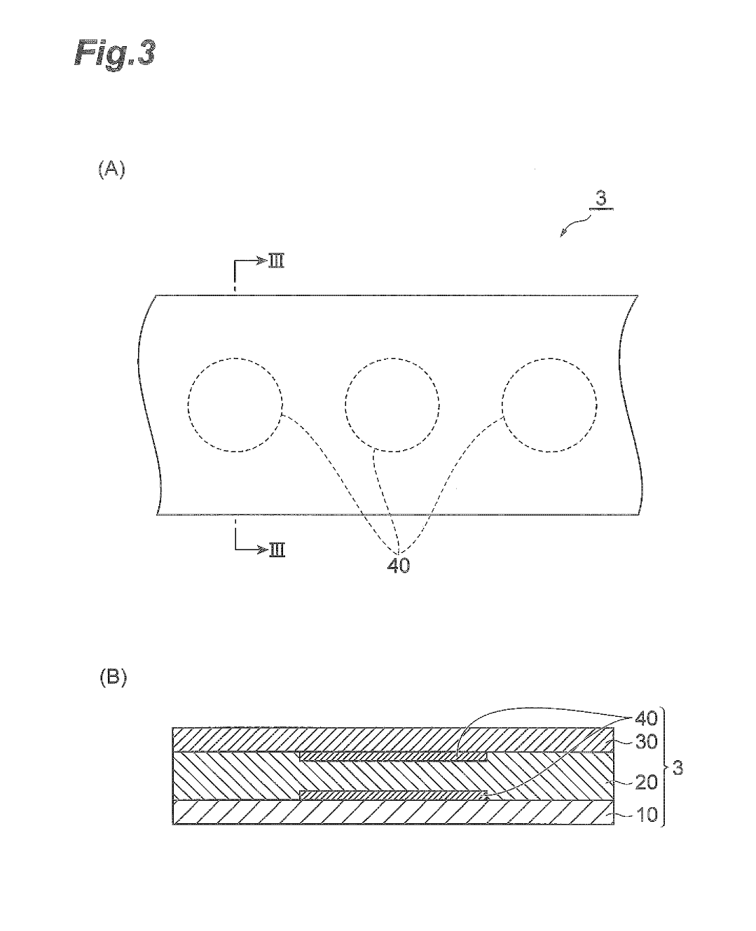

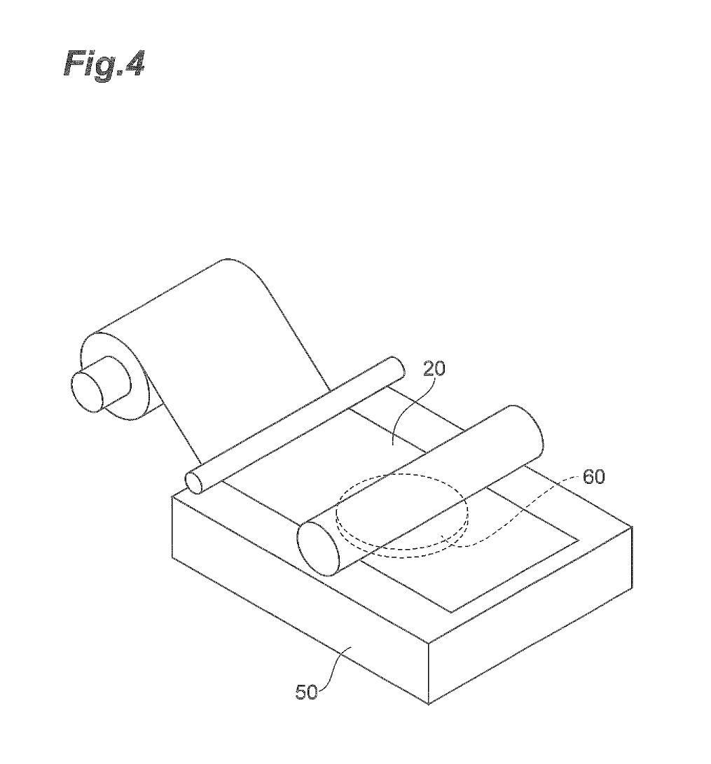

First, the temporary securing film 20 is prepared. Subsequently, as illustrated in FIG. 4, a roll laminator 50 attaches the temporary securing film 20 onto a circular support member 60 made of glass or a wafer. After being attached, the temporary securing film is cut into a circle according to the form of the support member. Here, it is preferred for the cutting form to be set also according to the form of the semiconductor wafer to be processed.

Though the temporary securing film 20 is used in this embodiment, the above-mentioned temporary securing film sheet 1 may be prepared and, after peeling the protective film 30, the temporary securing film 20 may be attached onto the support member 60 while peeling the support base 10. The cutting step may be omitted when the above-mentioned temporary securing film sheet 2 is used.

Not only the roll laminator, but a vacuum laminator may also be used for attaching the temporary securing film to the support member. The temporary securing film may be attached to the semiconductor wafer to be processed instead of the support member.

Next, the support member having the temporary securing film attached thereto is set on a vacuum press or a vacuum laminator, and the semiconductor wafer is bonded thereto under pressure by the press. When the temporary securing film is attached to the semiconductor wafer side, the wafer having the temporary securing film attached thereto is set on the vacuum press or vacuum laminator, and the support member is bonded thereto under pressure by the press.

When employing a vacuum press, the temporary securing film 20 is attached, for example, by using a vacuum press EVG (registered trademark) 500 series manufactured by EV Group at an atmospheric pressure of 1 hPa or less, a bonding pressure of 1 MPa, a bonding temperature of 120° C. to 200° C., and a holding time of 100 sec to 300 sec.

When employing a vacuum press, the temporary securing film 20 is attached, for example, by using a vacuum laminator LM-50×50-S manufactured by NPC, Inc. or a vacuum laminator V130 manufactured by Nichigo-Morton Co., Ltd. at an atmospheric pressure of 1 hPa or less, a bonding temperature of 60° C. to 180° C., preferably 80° C. to 150° C., a laminating pressure of 0.01 to 0.5 MPa, preferably 0.1 to 0.5 MPa, and a holding time of 1 sec to 600 sec, preferably 30 sec to 300 sec.

Thus, as illustrated in (A) of FIG. 5, a semiconductor wafer 70 is temporarily secured to the support member 60 while interposing the temporary securing film 20 therebetween.

As for the temperature condition at this time, using the temporary securing film in accordance with the present invention enables bonding at 200° C. or lower. This makes it possible to secure the support member and the semiconductor wafer to each other while fully preventing the semiconductor wafer from being damaged.

In this embodiment, the support member 60 has a release-processed surface 62 as a surface thereof. The release-processed surface 62 is formed by release-processing a part of the surface of the support member 60 with a release agent. Examples of the release agent include polyethylene-based waxes and fluorine-based waxes. Examples of the release-processing method include dipping, spin coating, and vapor deposition.

Also employable as the release agent are surface modifiers having a fluorine atom, polyolefin-based waxes, silicone oils, silicone oils having a reactive group, and silicone-modified alkyd resins.

Examples of the surface modifiers having a fluorine atom include commercially available products such as MEGAFACE (product name, manufactured by DIC Corporation), HYPERTECH (product name, manufactured by Nissan Chemical Industries, Ltd.), OPTOOL (product name, manufactured by Daikin Industries, Ltd.), and CHEMINOX (product name, manufactured by Unimatec Co., Ltd.).

Examples of polyolefin waxes include waxes based on polyethylene, amides, and montanoic acid.

Examples of silicone oils include a straight silicone oil (KF-96 (manufactured by Shin-Etsu Chemical Co., Ltd.)) and reactive silicone oils (X-22-176F, X-22-3710, X-22-173DX, and X-22-170BX (manufactured by Shin-Etsu Chemical Co., Ltd.)).

Examples of the silicone-modified alkyd resins include those used in the temporary securing film.

These release agents may be used singly or in combinations of two or more.

When the support member 60 is not formed with the release-processed surface 62, a release layer may be formed by applying a varnish containing a release agent onto the temporary securing film 20, for example.

As illustrated in (A) of FIG. 5, it is preferred for the release processing to be applied to not fringes but the center of the support member 60. This can secure the bonding strength to the temporary securing film during the processing of the semiconductor wafer and shorten the time required for dissolving the temporary securing film in an organic solvent after the processing.

In this embodiment, the semiconductor wafer 70 has an edge-trimmed disk shape and is temporary secured to the support member 60 while the temporary securing film 20 formed such as to have a diameter smaller than that of the side of the semiconductor wafer 70 having an edge trimming 75 is interposed between the edge trimming side of the semiconductor wafer and the support member. The semiconductor wafer 70 has a predetermined wiring pattern processed thereon, while the temporary securing film is attached to the surface having the wiring pattern.

The point mentioned above will now be explained in more detail. The outer peripheral part of the surface of the semiconductor wafer 70 opposing the support member 60 is provided with the edge trimming 75. For example, a temporary securing film having a circular form in planar view is used as the temporary securing film 20. The temporary securing film 20 has a radius smaller by a length D than that of the surface of the semiconductor wafer 70 opposing the support member 60.

The temporary securing film 20 is arranged such that the center of the surface of the semiconductor wafer 70 opposing the support member 60 and the center of the temporary securing film 20 align with each other. That is, the temporary securing film 20 is arranged at the length D inside of the edge-trimmed part 75.

Next, as illustrated in (B) of FIG. 5, a grinder 90 grinds the rear face of the semiconductor wafer (on the side opposite from the edge-trimmed side (surface having the wiring pattern) of the semiconductor wafer in this embodiment), so as to reduce the thickness of about 700 μm to 100 μm or less, for example.

For grinding with the grinder 90, a grinder DGP8761 manufactured by DISCO Corporation is used, for example. In this case, grinding conditions can be selected arbitrarily according to desired thickness and ground state of the semiconductor wafer.

Edge-trimming the semiconductor wafer makes it easy to restrain the wafer from being damaged in the grinding step thereof. Making the temporary securing film 20 smaller than the edge-trimmed side of the semiconductor wafer can prevent the temporary securing film from protruding out of the ground wafer, whereby residues of the temporary securing film can be kept from occurring and contaminating the semiconductor wafer in processing such as plasma etching, for example.

While the temporary securing film 20 is arranged at the length D inside of the edge-trimmed part 75 as mentioned above, the length D is preferably at least 1 mm but not more than 2 mm. When the length D is 1 mm or more, the temporary securing film 20 is less likely to protrude to the edge-trimmed part 75 even if an error occurs at a position arranged with the temporary securing film 20. When the length D is 2 mm or less, the flatness of the semiconductor wafer 70 can be secured, whereby the semiconductor wafer 70 can be ground favorably in the later grinding step.

Next, the rear side of the thinned semiconductor wafer 80 is subjected to processing such as dry ion etching or the Bosch process, so as to form through-holes, which are then subjected to processing such as copper plating, so as to form through-electrodes 82 (see (C) in FIG. 5).

Thus, predetermined processing is applied to the semiconductor wafer. (D) in FIG. 5 is a top plan view of the processed semiconductor wafer.

Thereafter, the processed semiconductor 80 is separated from the support member 60 and diced along dicing lines 84 into semiconductor elements. Thus obtained semiconductor element is connected to another semiconductor element or a substrate for mounting the semiconductor element, so as to yield a semiconductor device.

In another mode, a plurality of semiconductor wafers or semiconductor elements obtained by steps similar to those mentioned above may be stacked so that their through-hole electrodes are connected to each other, so as to yield a semiconductor device. When a plurality of semiconductor wafers are stacked, the resulting multilayer body may be cut by dicing, so as to yield a semiconductor device.

In still another mode, a thick semiconductor wafer formed beforehand with through-electrodes is prepared, the temporary securing film is attached to a circuit surface of the wafer, and the rear face of the semiconductor wafer (on the side opposite from the edge-trimmed side (surface having the wiring pattern) of the semiconductor wafer in this embodiment) may be ground with a grinder, so as to reduce the thickness of about 700 μm to 100 μm or less, for example. Subsequently, the thinned semiconductor wafer is etched, so as to expose the heads of the through-electrodes, and a passivation film is formed thereon. Thereafter, the heads of the copper electrodes are exposed again by ion etching or the like, so as to form a circuit. Thus, the processed semiconductor wafer can be obtained.

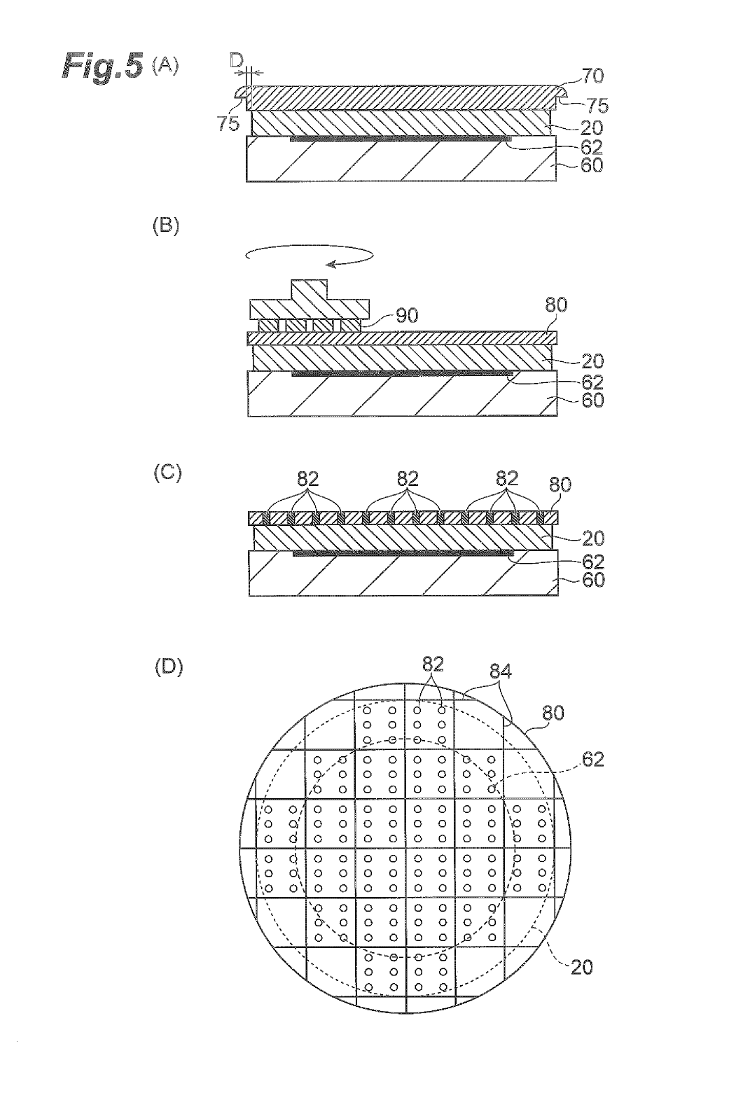

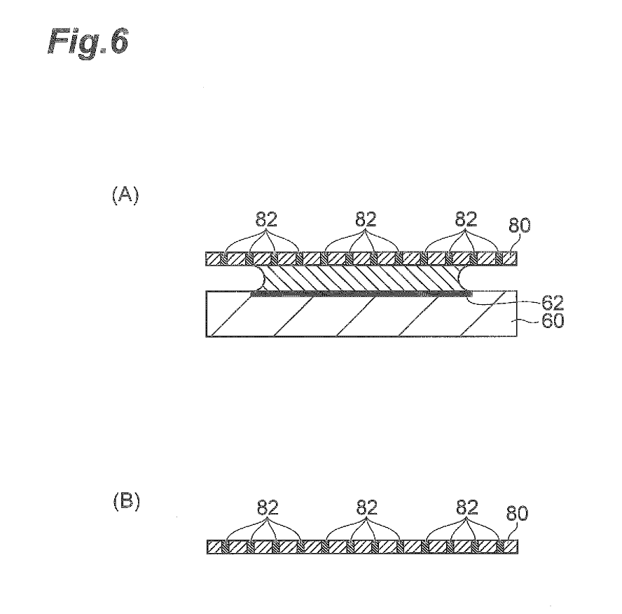

The processed semiconductor wafer 80 and the support member 60 can be separated from each other easily by bringing an organic solvent into contact with the temporary securing film 20 so as to dissolve a part or whole of the temporary securing film 20. This embodiment dissolves the temporary securing film 20 down to the release-processed surface 62 of the support member 60 as illustrated in (A) of FIG. 6, thereby making it possible to separate the processed semiconductor wafer 80 from the support member 60. This can reduce the time required for separation.

Examples of the organic solvent include N-methyl-2-pyrrolidinone (NMP), dimethylsulfoxide (DMSO), diethyleneglycol dimethyl ether (diglyme), cyclohexanone, trimethylammonium hydroxide (TMAH), and a mixed solvent of at least one of them and at least one of triethanolamine and alcohols. The organic solvent may be constituted by one compound or a mixture of two or more compounds. Preferred examples of the solvent include NMP, NMP/ethanolamine, NMP/TMAH aqueous solution, NMP/triethanolamine, (NMP/TMAH aqueous solution)/alcohol, TMAH aqueous solution, and TMAH aqueous solution/alcohol.

Examples of methods for bringing the organic solvent into contact with the temporary securing film 20 include dipping, spray cleaning, and ultrasonic cleaning. The temperature of the organic solvent is preferably 25° C. or higher, more preferably 40° C. or higher, and further preferably 60° C. or higher. The contact time with the organic solvent is preferably at least 1 min, more preferably at least 10 min, and further preferably at least 30 min.

For separating the semiconductor wafer 80 and the support member 60 from each other, for example, a key-shaped jig may be provided in a hanging fashion at an interface between the temporary securing film and the release-processed surface, and an upward stress may be applied thereto.

Thus, the semiconductor wafer subjected to predetermined processing can be obtained ((B) in FIG. 6). The temporary securing film 20, if any, remaining in the separated semiconductor wafer 80 can be cleaned again with the organic solvent or the like.

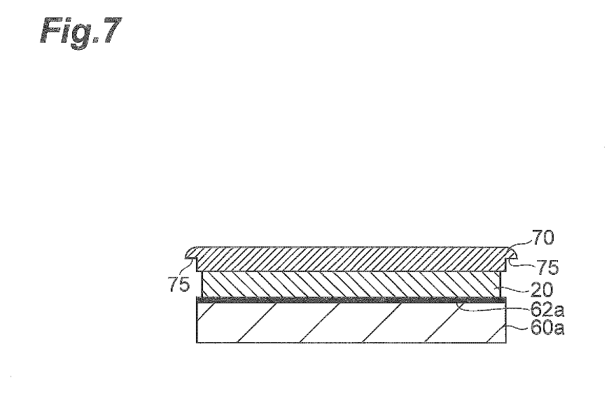

While the release-processed surface 62 is formed in a part of the surface of the support member 60 in the above-mentioned embodiment, a release-processed surface 62a may be formed on the whole surface of a support member 60a as illustrated in FIG. 7. This makes it easy to separate the processed semiconductor wafer 80 from the support member 60 mechanically at room temperature without using any solvent. For the mechanical separation, a de-bonding system EVG805EZD manufactured by EV Group is used, for example.

The release-processed surface 62a is formed by applying a surface modifier having a fluorine atom onto the whole surface of the support member 60a by spin coating, for example. In this case, for example, a fluorine-based release agent (OPTOOL HD-100Z) manufactured by Daikin Industries, Ltd.) is applied to the surface of the support member 60a by using a spin-coater MS-A200 manufactured by Mikasa Co., Ltd. for 10 sec to 30 sec at 1,000 rpm to 2,000 rpm and then left for 3 min in an oven set to 120° C., so as to vaporize the solvent, thereby forming the release-processed surface 62a.

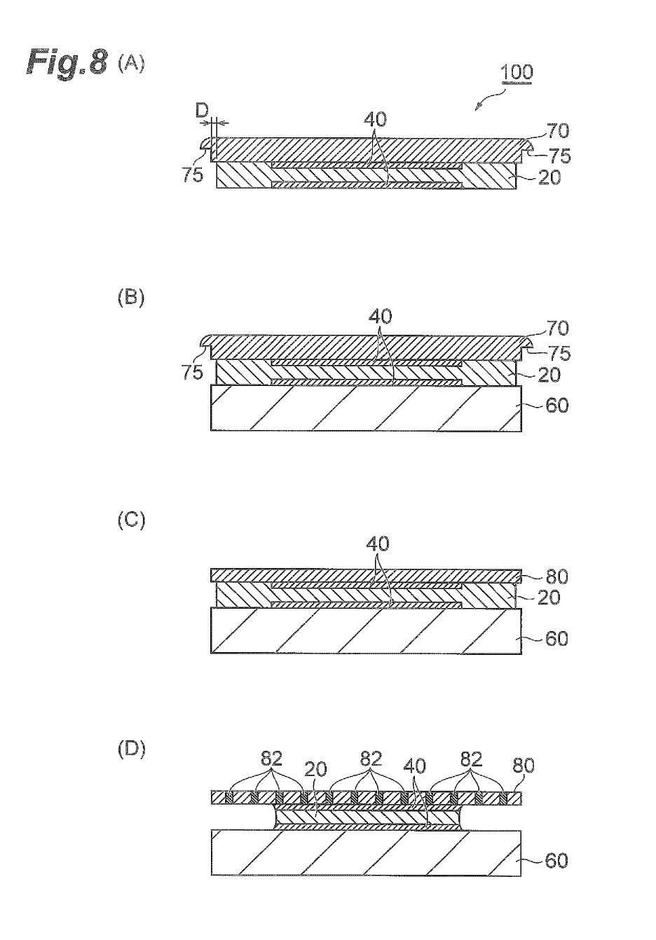

FIG. 8 illustrates an example of temporarily securing, processing, and separating a semiconductor wafer by using a temporary securing film sheet 3 as another embodiment.

This embodiment bonds the temporary securing film 20 to the side of the semiconductor wafer 70 provided with the edge trimming 75, so as to prepare a temporary-securing-film-equipped semiconductor wafer 100 ((A) in FIG. 8).

Subsequently, the temporary-securing-film-equipped semiconductor wafer 100 is set on a vacuum press or a vacuum laminator, and the support member 60 is attached thereto under pressure by the press. Thus, as illustrated in (B) of FIG. 8, the semiconductor wafer 70 is temporarily secured to the support member 60 while interposing therebetween the temporary securing film 20 having the low-adhesive-force layers on both sides.

Next, the rear face of the semiconductor wafer is ground ((C) in FIG. 8), and processing such as circuit formation and through-hole formation is further performed. Then, the organic solvent is brought into contact with the temporary securing film 20, so as to dissolve a part of the temporary securing film 20. Here, the temporary securing film 20 is dissolved down to the low-adhesive-force layers 40 as illustrated in (D) of FIG. 8, thereby making it possible to separate the processed semiconductor wafer 80 from the support member 60. This can also reduce the processing time required for separation.

The processed semiconductor wafer 80 is formed with through-electrodes and divided by dicing into semiconductor elements as mentioned above.

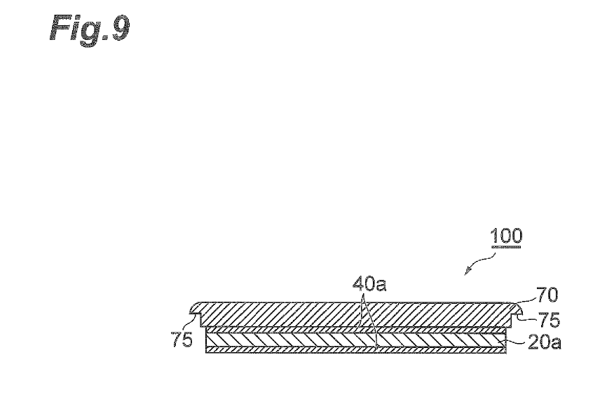

While the low-adhesive-force layers 40 are formed in a part of the surfaces of the temporary securing film 20 in the above-mentioned embodiment, low-adhesive-force layers 40a may be formed all over the surfaces of the temporary securing film 20 as illustrated in FIG. 9. This makes it easy to separate the processed semiconductor wafer 80 from the support member 60 mechanically at room temperature without using any solvent. For the mechanical separation, a de-bonding system EVG805EZD manufactured by EV Group is used, for example.

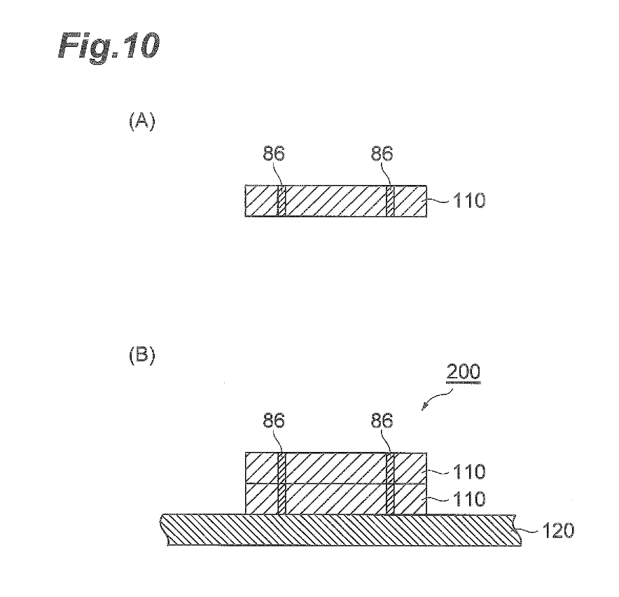

The above-mentioned method forms through-electrodes 86 and yields individually divided semiconductor elements 110 ((A) in FIG. 10).

A plurality of semiconductor elements 110 are stacked on a wiring board 120, for example. Thus, a semiconductor device 200 comprising the semiconductor elements 110 can be obtained ((B) in FIG. 10).

### EXAMPLES

In the following, the present invention will be explained more specifically with reference to examples without being limited thereto.

### Synthesis of a Polyimide Resin PI-1

In a flask equipped with a stirrer, a thermometer, a nitrogen substitution device (nitrogen inlet tube), and a reflux condenser with a water receptor, 10.26 g (0.025 mol) of BAPP (product name, 2,2-bis[4-(4-aminophenoxyl)phenyl]propane having a molecular weight of 410.51 manufactured by Tokyo Chemical Industry Co., Ltd.) and 5.10 g (0.025 mol) of 1,4-butanediol bis(3-aminopropyl)ether (product name: B-12, molecular weight: 204.31, manufactured by Tokyo Chemical Industry Co., Ltd.) as diamines and 100 g of N-methyl-2-pyrrolidone (NMP) as a solvent were put and stirred, so as to dissolve the diamines in the solvent.

While cooling the flask in an ice bath, 26.11 g (0.05 mol) of decamethylenebistrimellitate dianhydride (DBTA) was added little by little to the solution within the flask. After completing the addition, the solution was heated to 180° C. while blowing a nitrogen gas thereinto and held at this temperature for 5 hr, so as to yield a polyimide resin PI-1. The polyimide resin PI-1 had a weight-average molecular weight of 50,000 and a Tg of 70° C.

### Synthesis of a Polyimide Resin PI-2

In a flask equipped with a stirrer, a thermometer, a nitrogen substitution device (nitrogen inlet tube), and a reflux condenser with a water receptor, 8.21 g (0.02 mol) of BAPP (product name, 2,2-bis[4-(4-aminophenoxyl)phenyl]propane having a molecular weight of 410.51 manufactured by Tokyo Chemical Industry Co., Ltd.) and 28.8 g (0.003 mol) of a long-chain siloxane diamine (product name: KF8010, molecular weight: 960, manufactured by Shin-Etsu Chemical Co., Ltd.) as diamines and 100 g of N-methyl-2-pyrrolidone (NMP) as a solvent were put and stirred, so as to dissolve the diamines in the solvent.

While cooling the flask in an ice bath, 5.22 g (0.01 mol) of decamethylenebistrimellitate dianhydride (DBTA) and 13.04 g (0.04 mol) of 4,4′-oxydiphthalic acid dianhydride were added little by little to the solution within the flask. After completing the addition, the solution was heated to 180° C. while blowing a nitrogen gas thereinto and held at this temperature for 5 hr, so as to yield a polyimide resin PI-2. The polyimide resin PI-2 had a weight-average molecular weight of 50,000 and a Tg of 120° C.

### Synthesis of a Polyimide Resin PI-3

In a flask equipped with a stirrer, a thermometer, a nitrogen substitution device (nitrogen inlet tube), and a reflux condenser with a water receptor, 2.04 g (0.01 mol) of B-12 (1,4-butanediol bis(3-aminopropyl) ether having a molecular weight of 204.31 manufactured by Tokyo Chemical Industry Co., Ltd.), 10.23 g (0.035 mol) of 1,3-bis(3-aminophenoxy)benzene (APB-N having a molecular weight of 292.34 manufactured by Tokyo Chemical Industry Co., Ltd.), and 22 g (0.005 mol) of a long-chain siloxanediamine having a phenyl group at a side-chain (product name: X-22-1660B-3, molecular weight: 4,400, manufactured by Shin-Etsu Chemical Co., Ltd.) as diamines and 100 g of N-methyl-2-pyrrolidone (NMP) as a solvent were put and stirred, so as to dissolve the diamines in the solvent.

While cooling the flask in an ice bath, 26.11 g (0.05 mol) of decamethylenebistrimellitate dianhydride (DBTA) was added little by little to the solution within the flask. After completing the addition, the solution was heated to 180° C. while blowing a nitrogen gas thereinto and held at this temperature for 5 hr, so as to yield a polyimide resin PI-3. The polyimide resin PI-3 had a weight-average molecular weight of 70,000 and a Tg of 100° C.

### Synthesis of a Polyimide Resin PI-4

In a flask equipped with a stirrer, a thermometer, a nitrogen substitution device (nitrogen inlet tube), and a reflux condenser with a water receptor, 13.15 g (0.045 mol) of 1,3-bis(3-aminophenoxy)benzene (APB-N having a molecular weight of 292.34 manufactured by Tokyo Chemical Industry Co., Ltd.) and 22 g (0.005 mol) of a long-chain siloxanediamine having a phenyl group at a side-chain (product name: X-22-1660B-3, molecular weight: 4,400, manufactured by Shin-Etsu Chemical Co., Ltd.) as diamines and 100 g of N-methyl-2-pyrrolidone (NMP) as a solvent were put and stirred, so as to dissolve the diamines in the solvent.

While cooling the flask in an ice bath, 26.11 g (0.05 mol) of decamethylenebistrimellitate dianhydride (DBTA) was added little by little to the solution within the flask. After completing the addition, the solution was heated to 180° C. while blowing a nitrogen gas thereinto and held at this temperature for 5 hr, so as to yield a polyimide resin PI-4. The polyimide resin PI-2 had a weight-average molecular weight of 70,000 and a Tg of 160° C.

### Synthesis of a Polyimide Resin PI-5

In a flask equipped with a stirrer, a thermometer, a nitrogen substitution device (nitrogen inlet tube), and a reflux condenser with a water receptor, 20.52 g (0.05 mol) of BAPP (product name, 2,2-bis[4-(4-aminophenoxyl)phenyl]propane having a molecular weight of 410.51 manufactured by Tokyo Chemical Industry Co., Ltd.) as a diamine and 100 g of N-methyl-2-pyrrolidone (NMP) as a solvent were put and stirred, so as to dissolve the diamine in the solvent.

While cooling the flask in an ice bath, 10.90 g (0.05 mol) of pyromellitic acid anhydride was added little by little to the solution within the flask. After completing the addition, the solution was heated to 180° C. while blowing a nitrogen gas thereinto and held at this temperature for 5 hr, so as to yield a polyimide resin PI-5. The polyimide resin PI-5 had a weight-average molecular weight of 30,000 and a Tg of 200° C.

Table 1 lists compositions of the polyimides PI-1 to 5 (in terms of mol % based on the whole amount of acid anhydrides or diamines).

TABLE 1

| | | PI-1 | PI-2 | PI-3 | PI-4 | PI-5 |
|---|---|---|---|---|---|---|
| Acid | DBTA | 100 | 20 | 100 | 100 | — |
| anhydride | ODPA | — | 80 | — | — | — |
| | Pyromellitic | — | — | — | — | 100 |
| | acid | | | | | |
| | anhydride | | | | | |
| Diamine | BAPP | 50 | 40 | — | — | 100 |
| | B-12 | 50 | — | 20 | — | — |
| | KF8010 | — | 60 | — | — | — |
| | X-22-1660B-3 | — | — | 10 | 10 | — |
| | APB-N | — | — | 70 | 90 | — |

### Examples 1 to 14 and Comparative Examples 1 and 2

Varnishes for forming films were made by dissolving and mixing materials in an NMP solvent so as to yield a solid content of 50 mass % according to the compositions (in units of parts by mass) listed in Tables 2 to 4.

TABLE 2

| | | Exam- | Exam- | | Exam- |
|---|---|---|---|---|---|
| | | ple 1 | ple 2 | Example 3 | ple 4 |
| Resin | PI-1 | 100 | 100 | 100 | — |
| | PI-2 | — | — | — | 100 |
| | PI-3 | — | — | — | — |
| | PI-4 | — | — | — | — |
| Radically | A-DCP | — | 10 | 10 | — |
| polymerizable | | | | | |
| compound | | | | | |
| Thermal | PERCUMYL | — | 1 | 1 | — |
| radical | D | | | | |
| generator | | | | | |
| Filler | H27 | — | 50 | 50 | — |
| | SC2050SEJ | 50 | — | — | 50 |
| Surface | HD1100Z | — | — | 1 | — |
| modifier | FA-200 | — | — | — | — |
| Additive | 2PZ-CN | 1 | — | — | 1 |
| | | Exam- | Exam- | | Exam- |
| | | ple 5 | ple 6 | Example 7 | ple 8 |
| Resin | PI-1 | — | — | — | — |
| | PI-2 | 100 | 100 | — | — |
| | PI-3 | — | — | 100 | — |
| | PI-4 | — | — | — | 100 |
| Radically | A-DCP | 10 | 10 | — | — |
| polymerizable | | | | | |
| compound | | | | | |
| Thermal | PERCUMYL | 1 | 1 | — | — |
| radical | D | | | | |
| generator | | | | | |
| Filler | H27 | 50 | 50 | 50 | 50 |
| | SC2050SEJ | — | — | — | — |
| Surface | HD1100Z | — | — | — | — |
| modifier | FA-200 | — | 1 | — | — |
| Additive | 2PZ-CN | — | — | — | — |

TABLE 3

| | | Exam- | Exam- | Exam- | Example |
|---|---|---|---|---|---|
| | | ple 9 | ple 10 | ple 11 | 12 |
| Resin | PI-1 | 100 | 100 | 100 | 100 |
| | PI-2 | — | — | — | — |
| | PI-3 | — | — | — | — |
| | PI-4 | — | — | — | — |
| Radically | A-DCP | — | — | — | — |
| polymerizable | A-9300 | 10 | — | — | 10 |
| compound | A-DOG | — | 10 | — | — |
| | UA-512 | — | — | 10 | — |
| Epoxy resin | YDF-8170 | — | — | — | 10 |
| | VG-3101 | — | — | — | — |
| Thermal | PERCUMYL | 1 | 1 | 1 | 1 |
| radical | D | | | | |
| generator | | | | | |
| Filler | H27 | 50 | 50 | 50 | 50 |
| | SC2050SEJ | — | — | — | — |
| Surface | HD1100Z | — | — | — | — |
| modifier | FA-200 | — | — | — | — |
| Additive | 2PZ-CN | — | — | — | 1 |

| | | Example | Example |
|---|---|---|---|
| | | 13 | 14 |
| Resin | PI-1 | 100 | 100 |
| | PI-2 | — | — |
| | PI-3 | — | — |
| | PI-4 | — | — |
| Radically | A-DCP | 10 | |
| polymerizable | A-9300 | — | 25 |
| compound | A-DOG | — | — |
| | UA-512 | — | — |
| Epoxy resin | YDF-8170 | 10 | 25 |
| | VG-3101 | 10 | — |
| Thermal | PERCUMYL | 1 | 1 |
| radical | D | | |
| generator | | | |
| Filler | H27 | 50 | 50 |
| | SC2050SEJ | — | — |
| Surface | HD1100Z | — | — |
| modifier | FA-200 | — | — |
| Additive | 2PZ-CN | 1 | 1 |

TABLE 4

| | | Comparative | Comparative |
|---|---|---|---|
| | | Example 1 | Example 2 |
| Resin | PI-5 | 100 | |
| | SK-Dyne1435 | | 100 |

Details of the components in the tables are as follows:

SK-Dyne 1435: acrylic adhesive (manufactured by Soken Chemical & Engineering Co., Ltd.)
A-DCP: tricyclodecanedimethanol diacrylate (manufactured by Shin Nakamura Chemical Co., Ltd.)
A-9300: ethoxylated isocyanuric acid triacrylate (manufactured by Shin Nakamura Chemical Co., Ltd.)
A-DOG: 1,10-decanediol acrylate (manufactured by Shin Nakamura Chemical Co., Ltd.)
UA-512: bifunctional urethane acrylate (manufactured by Shin Nakamura Chemical Co., Ltd.)
YDF-8170: bisphenol F type bis(glycidyl ether) (manufactured by Tohto Kasei Co., Ltd.)
VG-3101: highly heat-resistant trifunctional epoxy resin (manufactured by Printec Corporation)
PERCUMYL D: dicumyl peroxide (manufactured by NOF Corporation)
H27: trimethoxyphenylsilane-modified spherical silica filler (manufactured by CIK NanoTek Corporation)
SC2050SEJ: 3-glycidoxypropyltrimethoxysilane-modified silica filler
HD 1100Z: fluorine-based surface modifier (manufactured by Daikin Industries, Ltd.)
FA-200: fluorine-based surface modifier (manufactured by Nissan Chemical Industries, Ltd.)
2PZ-CN: imidazole-based curing accelerator (manufactured by Shikoku Chemicals Corporation)

Making of Temporary Securing Films

Each of thus prepared varnishes was applied onto a separator film (PET film) with a knife coater and subsequently dried for 30 min in an oven at 80° C. and then 30 min in an oven at 120° C., so as to make a temporary securing film having a thickness of 30 μm.

For thus obtained temporary securing films, low-temperature adhesiveness, heat resistance, and solubility were evaluated according to the following tests. Table 4 lists results.

Low-Temperature Adhesiveness Test

Each temporary securing film was pressed by a roll (having a temperature of 150° C., a linear pressure of 4 kgf/cm, and a feed rate of 0.5 m/min) so as to be layered on the rear face (surface opposite from a support table) of a silicon wafer (having a diameter of 6 inches and a thickness of 400 m) mounted on the support table. The PET film was peeled off, and a polyimide film “Upilex” (product name) having a thickness of 80 μm, a width of 10 mm, and a length of 40 mm was pressed onto the temporary securing film under the condition same as above, so as to form a layer. Thus prepared sample was subjected to a 90° peel test at room temperature with a rheometer “Strograph E-S” (product name), so as to measure the peel strength between the temporary securing film and Upilex. Samples with the peel strength of 2 N/cm or greater were labeled A, the others C.

Adhesive Force (Sticking Force) Test

Each temporary securing film was pressed by a roll (having a temperature of 80° C., a linear pressure of 4 kgf/cm, and a feed rate of 0.5 m/min) so as to be layered on the rear face (surface opposite from a support table) of a silicon wafer (having a diameter of 6 inches and a thickness of 400 μm) mounted on the support table. The PET film was peeled off, and a pressure-sensitive dicing tape was laminated on the temporary securing film. Thereafter, the wafer was divided by a dicer into chips each having a size of 3 mm×3 mm. Each of thus obtained chips with the temporary securing film was bonded under pressure and heat onto a silicon substrate having a size of 10 mm×10 mm and a thickness of 0.40 mm with the temporary securing film facing the latter under a condition of 2,000 gf/10 sec on a heating plate at 150° C. Thereafter, it was heated for 1 hr at 120° C., 1 hr at 180° C., and 10 min at 260° C. For each of thus obtained samples, the adhesive force occurring at the time when applying an external force in a shearing direction to the chip side was measured on a heating plate at 25° C. by using an adhesive force tester Dage-4000 manufactured by Dage under conditions with a measurement rate of 50 m/sec and a measurement height of 50 μm and taken as the shear adhesive force at 25° C. Those having the shear adhesive force at 25° C. of 1 MPa or greater were labeled A, the others C.

Heat Resistance Test

Each of samples obtained as in the above-mentioned low-temperature adhesiveness test was heated on a hot plate for 1 hr at 120° C., 1 hr at 180° C., and 10 min at 260° C. Thereafter, the samples were observed, and those showing no bubbles were labeled A, the others C.

Solubility Test a

Each temporary securing film was pressed by a roll (having a temperature of 150° C., a linear pressure of 4 kgf/cm, and a feed rate of 0.5 m/min) so as to be layered on the rear face (surface opposite from a support table) of a ¼ silicon wafer (having a diameter of 6 inches and a ¼ of a thickness of 400 μm) mounted on the support table. The PET film was peeled off, and then each sample obtained as in the low-temperature adhesiveness test was heated on a hot plate for 1 hr at 120° C., 1 hr at 180° C., and 10 min at 260° C. Thereafter, the sample was put in a glass container filled with MNP, and an ultrasonic cleaner was used for dissolving the temporary securing film. Samples having dissolved the temporary securing film and not were labeled A and C, respectively.

Solubility Test B

Each temporary securing film was pressed by a roll (having a temperature of 150° C., a linear pressure of 4 kgf/cm, and a feed rate of 0.5 m/min) so as to be layered on the rear face (surface opposite from a support table) of a ¼ silicon wafer (having a diameter of 6 inches and a ¼ of a thickness of 400 μm) mounted on the support table. The PET film was peeled off, and then each sample obtained as in the low-temperature adhesiveness test was heated on a hot plate for 1 hr at 120° C., 1 hr at 180° C., and 10 min at 260° C. Thereafter, the sample was put into a glass container filled with a mixed solvent in which n-propylalcohol and a 25% TMAH aqueous solution were mixed at the same volume, and an ultrasonic cleaner was used for dissolving the temporary securing film. Samples having dissolved the temporary securing film and not were labeled A and C, respectively.

TABLE 5

| | Example 1 | Example 2 | Example 3 | Example 4 |
|---|---|---|---|---|
| Low-temperature | A | A | A | A |
| adhesiveness test | | | | |
| Adhesion test | A | A | A | A |
| Heat resistance | A | A | A | A |
| test | | | | |
| Solubility test A | A | A | A | A |
| Solubility test B | A | A | A | A |
| | Example 5 | Example 6 | Example 7 | Example 8 |
| Low-temperature | A | A | A | A |
| adhesiveness test | | | | |
| Adhesion test | A | A | A | A |
| Heat resistance | A | A | A | A |
| test | | | | |
| Solubility test A | A | A | A | A |
| Solubility test B | A | A | A | A |

TABLE 6

| | | Example | Example | Example |
|---|---|---|---|---|
| | Example 9 | 10 | 11 | 12 |
| Low-temperature | A | A | A | A |
| adhesiveness test | | | | |
| Adhesion test | A | A | A | A |
| Heat resistance | A | A | A | A |
| test | | | | |
| Solubility test A | A | A | A | C |
| Solubility test B | A | A | A | A |

| | Example 13 | Example 14 |
|---|---|---|
| Low-temperature | A | A |
| adhesiveness test | | |
| Adhesion test | A | A |
| Heat resistance test | A | A |
| Solubility test A | C | C |
| Solubility test B | A | A |

TABLE 7

| | Comparative | Comparative |
|---|---|---|
| | Example 1 | Example 2 |
| Low-temperature | C | A |
| adhesiveness test | | |
| Adhesion test | A | A |
| Heat resistance test | A | C |
| Solubility test A | A | A |
| Solubility test B | A | A |

Examples using acrylic rubber for the temporary securing film and their comparative examples will now be explained.

### Synthesis of Acrylic Rubber P-1

In a 500-cc separable flask equipped with a stirrer, a thermometer, a nitrogen substitution device (nitrogen inlet tube), and a reflux condenser with a water receptor, 200 g of deionized water, 40 g of butyl acrylate, 28 g of ethyl acrylate, 3 g of glycidyl methacrylate, 29 g of acrylonitrile, 2.04 g of a 1.8% polyvinylalcohol aqueous solution, 0.41 g of lauryl peroxide, and 0.07 g of n-octylmercaptan were compounded. Subsequently, an N₂ gas was blown into the system for 60 min, so as to purge air from therewithin, and then the temperature within the system was raised to 65° C., at which polymerization was carried out for 3 hr. The temperature was further raised to 90° C., at which stirring was continued for 2 hr, so as to complete the polymerization. The resulting transparent beads were separated by filtration, washed with ionized water, and then dried by a vacuum dryer at 50° C. for 6 hr, so as to yield acrylic rubber P-1. When measured by GPC, the weight-average molecular weight Mw of the acrylic rubber P-1 was 400,000 in terms of polystyrene. The Tg of the acrylic rubber P-1 was 8° C.

Here, a peak temperature of tan δ when measuring a film of the acrylic rubber by a viscoelastometer (manufactured by Rheometrics, Inc.) was taken as the Tg of the acrylic rubber. Specifically, a film having a thickness of 30 Lm was formed and then cut into a size of 10 mm×25 mm, and its storage elastic modulus and temperature dependency of tan δ were measured under conditions with a temperature raising rate of 5° C./min, a frequency of 1 Hz, and a measurement temperature of −50 to 300° C., so as to calculate the Tg.

### Synthesis of Acrylic Rubber P-2

In a 500-cc separable flask equipped with a stirrer, a thermometer, a nitrogen substitution device (nitrogen inlet tube), and a reflux condenser with a water receptor, 200 g of deionized water, 36 g of butyl acrylate, 18 g of ethyl acrylate, 3 g of glycidyl methacrylate, 43 g of methyl methacrylate, 2.04 g of a 1.8% polyvinylalcohol aqueous solution, 0.41 g of lauryl peroxide, and 0.07 g of n-octylmercaptan were compounded. Subsequently, an N₂ gas was blown into the system for 60 min, so as to purge air from therewithin, and then the temperature within the system was raised to 65° C., at which polymerization was carried out for 3 hr. The temperature was further raised to 90° C., at which stirring was continued for 2 hr, so as to complete the polymerization. The resulting transparent beads were separated by filtration, washed with ionized water, and then dried by a vacuum dryer at 50° C. for 6 hr, so as to yield acrylic rubber P-2. When measured by GPC, the weight-average molecular weight Mw of the acrylic rubber P-2 was 500,000. The Tg of the acrylic rubber P-2 was 12° C.

### Synthesis of Acrylic Rubber P-3

In a 500-cc separable flask equipped with a stirrer, a thermometer, a nitrogen substitution device (nitrogen inlet tube), and a reflux condenser with a water receptor, 200 g of deionized water, 59 g of butyl acrylate, 41 g of ethyl acrylate, 2.04 g of a 1.8% polyvinylalcohol aqueous solution, 0.41 g of lauryl peroxide, and 0.07 g of n-octylmercaptan were compounded. Subsequently, an N₂ gas was blown into the system for 60 min, so as to purge air from therewithin, and then the temperature within the system was raised to 65° C., at which polymerization was carried out for 3 hr. The temperature was further raised to 90° C., at which stirring was continued for 2 hr, so as to complete the polymerization. The resulting transparent beads were separated by filtration, washed with ionized water, and then dried by a vacuum dryer at 50° C. for 6 hr, so as to yield acrylic rubber P-3. When measured by GPC, the weight-average molecular weight Mw of the acrylic rubber P-3 was 400,000. The Tg of the acrylic rubber P-3 was −40° C.

Preparation of Varnishes

Varnishes F-01 to F-07 were prepared by compounding acrylic rubbers, curing accelerators, release agents, fillers, and coating solvents in compounding ratios (in units of parts by mass) listed in Table 8.

TABLE 8

| | | F-01 | F-02 | F-03 | F-04 | F-05 | F-06 | F-07 |
|---|---|---|---|---|---|---|---|---|
| Acrylic | P-1 | 100 | — | — | — | 100 | — | — |
| rubber | P-2 | — | 100 | — | — | — | — | — |
| | P-3 | — | — | 100 | — | — | — | — |
| | HTR-860P- | — | — | — | 100 | — | 100 | 100 |
| | DR3 | | | | | | | |
| Curing | 2PZ-CN | 1 | 1 | 1 | 1 | 1 | 1 | 1 |
| acceler- | | | | | | | | |
| ator | | | | | | | | |
| Release | TA31-209E | 20 | 20 | 20 | 20 | — | — | 20 |
| agent | | | | | | | | |
| Filler | SC2050-SEJ | — | — | — | — | — | — | 20 |
| Coating | Cyclo- | 200 | 200 | 200 | 200 | 200 | 200 | 200 |
| solvent | hexanone | | | | | | | |

Details of the components in the tables are as follows:

HTR-860P-DR3: acrylic rubber having the weight-average molecular weight of 800,000 according to GPC, 3 mass % of glycidyl methacrylate, and Tg of −7° C. (manufactured by Nagase ChemteX Corporation)
2PZ-CN: imidazole-based curing accelerator (manufactured by Shikoku Chemicals Corporation)
TA31-209E: silicone-modified alkyd resin (manufactured by Hitachi Kasei Polymer Co., Ltd.)
SC2050-SEJ: surface processing silica filler (manufactured by Admatechs Co., Ltd.)

Making of Temporary Securing Films

Each of thus prepared varnishes was applied onto a release-processed polyethylene terephthalate film having a thickness of 50 μm and dried by heating at 90° C. for 10 min and then at 120° C. for 30 min, so as to yield a temporary securing film with a base film. The thickness of the temporary securing film was 30 μm.

Making of a Support Member R-1 with a Release Agent

An 8-inch wafer was set in a spin-coater MS-A200 manufactured by Mikasa Co., Ltd. with its mirror-finished surface side facing up, a fluorine-based release agent manufactured by Daikin Industries, Ltd. (OPTOOL HD-1000Z) was dripped on the wafer, and then spin coating was carried out at 800 rpm for 10 sec and subsequently at 1200 rpm for 30 sec. Thereafter, the wafer was left for 5 min on a hot plate set at 120° C. and subsequently 5 min on a hot plate set at 150° C., so as to yield a support member R-1 with a release agent.

Making of a Support Member R-2 with a Release Agent

An 8-inch wafer was set in a spin-coater MS-A200 manufactured by Mikasa Co., Ltd. with its mirror-finished surface side facing up, a toluene solution containing 10 mass % of a solid content in which 100 parts by mass of a silicone-modified alkyd resin (TA31-209E) manufactured by Hitachi Kasei Polymer Co., Ltd. and 10 parts by mass of p-toluenesulfonic acid were compounded was dripped on the wafer, and then spin coating was carried out at 800 rpm for 10 sec and subsequently at 1500 rpm for 30 sec. Thereafter, the wafer was left for 5 min on a hot plate set at 120° C. and subsequently 5 min on a hot plate set at 150° C., so as to yield a support member R-2 with a release agent.

Support Member R-3

An 8-inch wafer was used as it was as a support member R-3 without release-processing.

### Examples 15 to 19 and Comparative Examples 3 to 8

In a procedure which will be explained in the following, the above-mentioned acrylic rubbers in the state of a varnish or temporary securing film were combined with the above-mentioned support members and evaluated in various ways. Tables 9 and 10 list kinds of acrylic rubbers used, states of the acrylic rubbers, kinds of the support members, and results of evaluations.

Edge Trimming of the Semiconductor Wafer

The unground semiconductor wafer was subjected to edge trimming with a fully automatic dicer (DFD-6316 manufactured by DISCO corporation). As a blade, VT07-SD2000-VC200-100 (52×1A3×40-L) manufactured by DISCO corporation was used under conditions with a blade rotation speed of 20,000 rpm, a feed rate of 3.0°/sec, a cutting depth of 0.2 mm, and a trim width of 0.5 mm.

Film Lamination on the Semiconductor Wafer

The temporary securing film with the base film was cut out into a circle having a diameter smaller by 2 mm than the diameter of the edge-trimmed surface of the semiconductor wafer. Thereafter, lamination was carried out with a vacuum laminator V130 manufactured by Nichigo-Morton Co., Ltd. at an atmospheric pressure of 1 hPa or less, a bonding temperature of 80° C., a laminating pressure of 0.5 MPa, and a holding time of 60 sec, so as to yield a semiconductor wafer with a temporary securing film.

Spin Coating of the Semiconductor Wafer with Varnishes

The edge-trimmed semiconductor wafer was set in a spin-coater MS-A200 manufactured by Mikasa Co., Ltd., an appropriate amount of the varnishes listed in Table 1, and then spin coating was carried out at 600 rpm for 10 sec and subsequently at 1500 rpm for 30 sec. Thereafter, the wafer was dried by heating for 10 min in an oven set at 90° C. and subsequently 30 min in an oven set at 120° C., so as to yield a semiconductor wafer with a temporary securing film. The thickness of the temporary securing film was 30 μm.

Pressure-Bonding to the Support Member

The support member with the release agent and the semiconductor wafer with the temporary securing film were pressure-bonded to each other by using a vacuum laminator V130 manufactured by Nichigo-Morton Co., Ltd. at an atmospheric pressure of 1 hPa or less, a bonding temperature of 100° C., a laminating pressure of 0.5 MPa, and a holding time of 100 sec. Thereafter, it was held for 30 min in an oven set at 110° C. and then 1 hr in an oven set at 170° C., so as to yield a multilayer sample.

Backgrind Test

The semiconductor wafer surface of each multilayer sample was ground by a fully automatic grinder/polisher (DGP-8761 manufactured by DISCO Corporation). Used as wheels were GF01-SDC320-BT300-50, IF-01-1-4/6-B K09, and DPEG-GA0001 for the first, second, and third axes, respectively. The grinding was carried out in a cross-feed scheme with a chuck table rotation speed of 300 rpm and wheel rotation speeds of 3,200 rpm, 3,400 rpm, and 1,400 rpm at the first, second, and third axes, respectively. The grinding was effected by the first axis until the thickness became 142 μm, and then by the second and third axes to 102 μm and 100 μm, respectively. At the time when the grinding was completed, samples not incurring cracks and the like were evaluated A, the others B.

Heat Resistance Test

For each of the multilayer samples evaluated A in the background test, the state of the temporary securing film was seen by using SAM. Thereafter, the multilayer sample was left for 2 hr in an oven set at 200° C. and then 20 min in an oven set at 260° C. Subsequently, the state of the temporary securing film was seen by using SAM again, and the samples having no peel-off of the temporary securing film after being left in the ovens were evaluated A, the others B.

Releasability Test from the Support Member

For each of the multilayer samples evaluated A in the heat resistance test, tweezers having sharp leading ends were inserted between the support member coated with the release agent and the temporary securing film and moved along the outer periphery. Here, the samples from which the support member could be peeled without breaking the semiconductor wafer were evaluated A, the others B.

Releasability Test from the Semiconductor Wafer

For each of the multilayer samples evaluated A in the releasability test from the support member, an end part of the temporary securing film attached to the semiconductor wafer was lifted up by tweezers. Here, the samples from which the support member could be peeled were evaluated A, the others B.

TABLE 9

| | | Example | Example | Example |
|---|---|---|---|---|
| | | 15 | 16 | 17 |
| Combination | Acrylic rubber type | F-01 | F-02 | F-03 |
| | Acrylic rubber state | film | film | film |
| | Support member | R-1 | R-2 | R-1 |
| Test | Backgrind test | A | A | A |
| | Heat resistance test | A | A | A |
| | Releasability test | A | A | A |
| | from support | | | |
| | member | | | |
| | Releasability test | A | A | A |
| | from semiconductor | | | |
| | wafer | | | |

| | | Example | Example |
|---|---|---|---|
| | | 18 | 19 |
| Combination | Acrylic rubber type | F-04 | F-07 |
| | Acrylic rubber state | film | film |
| | Support member | R-2 | R-1 |
| Test | Backgrind test | A | A |
| | Heat resistance test | A | A |
| | Releasability test | A | A |
| | from support | | |
| | member | | |
| | Releasability test | A | A |
| | from semiconductor | | |
| | wafer | | |

TABLE 10

| | | Comp. | Comp. | Comp. |
|---|---|---|---|---|
| | | Ex. 3 | Ex. 4 | Ex. 5 |
| Combination | Acrylic rubber type | F-01 | F-01 | F-03 |
| | Acrylic rubber state | varnish | film | film |
| | Support member | R-1 | R-3 | R-1 |
| Test | Backgrind test | B | A | A |
| | Heat resistance test | — | A | B |
| | Releasability test | — | B | — |
| | from support | | | |
| | member | | | |
| | Releasability test | — | — | — |
| | from semiconductor | | | |
| | wafer | | | |
| | | Comp. | Comp. | Comp. |
| | | Ex. 6 | Ex. 7 | Ex. 8 |
| Combination | Acrylic rubber type | F-04 | F-05 | F-06 |
| | Acrylic rubber state | varnish | film | film |
| | Support member | R-2 | R-1 | R-1 |
| Test | Backgrind test | B | A | A |
| | Heat resistance test | — | A | A |
| | Releasability test | — | A | A |
| | from support | | | |
| | member | | | |
| | Releasability test | — | B | B |
| | from semiconductor | | | |
| | wafer | | | |

### REFERENCE SIGNS LIST

1, 2, 3: temporary securing film sheet; 10: support base; 20: temporary securing film; 30: protective film; 40: low-adhesive-force layer; 50: roll laminator, 60: support member; 62: release-processed surface; 70: semiconductor wafer; 75: edge trimming; 80: semiconductor wafer; 82: through hole; 84: dicing line; 86: through-electrode; 90: grinder; 100: semiconductor wafer with a temporary securing film; 110: semiconductor element; 120: wiring substrate; 200: semiconductor device.

1. A method for producing a semiconductor device comprising a semiconductor element obtained by dividing a semiconductor wafer, the method comprising:
a temporary securing step of arranging a temporary securing film between a support member and the semiconductor wafer so as to temporarily secure the support member and the semiconductor wafer to each other;
a grinding step of grinding a surface on the side opposite from the temporary securing film of the semiconductor wafer temporarily secured to the support member; and
a semiconductor wafer peeling step of peeling the temporary securing film from the ground semiconductor wafer;
wherein a semiconductor wafer edge-trimmed on an outer peripheral part of a surface opposing the support member is used as the semiconductor wafer; and
wherein the temporary securing step arranges the temporary securing film on the inside of the edge-trimmed part.

2. A method for producing a semiconductor device according to claim 1, further comprising a support member peeling step of peeling the temporary securing film from the support member;
wherein a support member release-processed on a part or whole of a surface opposing the temporary securing film is used as the support member.

3. A method for producing a semiconductor device according to claim 2, wherein the release processing is conducted by at least one release agent selected from the group consisting of a surface modifier having a fluorine atom, a polyolefin-based wax, a silicone oil, a silicone oil having a reactive group, and a silicone-modified alkyd resin.

4. A method for producing a semiconductor device according to claim 1, wherein a temporary securing film comprising a (meth)acrylic copolymer having an epoxy group is used as the temporary securing film, the (meth)acrylic copolymer obtained by polymerizing an acrylic monomer comprising an acrylate monomer having an epoxy group or a methacrylate monomer having an epoxy group, and having a weight-average molecular weight of at least 100,000 and a Tg of −50° C. to 50° C.

5. A method for producing a semiconductor device according to claim 4, wherein a glycidyl acrylate monomer is used as the acrylate monomer having an epoxy group, and wherein a glycidyl methacrylate monomer is used as the methacrylate monomer having an epoxy group.

6. A method for producing a semiconductor device according to claim 1, wherein a temporary securing film comprising a silicone-modified alkyd resin is used as the temporary securing film.

7. A method for producing a semiconductor device according to claim 2, wherein a temporary securing film comprising a (meth)acrylic copolymer having an epoxy group is used as the temporary securing film, the (meth)acrylic copolymer obtained by polymerizing an acrylic monomer comprising an acrylate monomer having an epoxy group or a methacrylate monomer having an epoxy group, and having a weight-average molecular weight of at least 100,000 and a Tg of −50° C. to 50° C.

8. A method for producing a semiconductor device according to claim 2, wherein a temporary securing film comprising a silicone-modified alkyd resin is used as the temporary securing film.
